(19) United States
(12) Patent Application Publication
(10) Pub. No.: US 2025/0146121 A1
(43) Pub. Date: May 8, 2025

(54) MASK AND METHOD OF MANUFACTURING MASK

(71) Applicant: DAI NIPPON PRINTING CO., LTD., Tokyo (JP)

(72) Inventors: Yasuko SONE, Tokyo (JP); Yutaka OZAWA, Tokyo (JP); Masashi HIRABAYASHI, Tokyo (JP)

(73) Assignee: DAI NIPPON PRINTING CO., LTD., Tokyo (JP)

(21) Appl. No.: 18/833,520

(22) PCT Filed: Jan. 31, 2023
(86) PCT No.: PCT/JP2023/002975

§ 371 Date: Jul. 26, 2024

(30) Foreign Application Priority Data
Jan. 31, 2022 (JP) 2022-013724
Dec. 12, 2022 (JP) 2022-198258

(51) Int. Cl. C23C 14/04; H10K 71/16

(52) U.S. Cl. CPC C23C 14/042; H10K 71/166

(57) ABSTRACT

A mask includes a first layer that includes a first surface, a second surface that is located opposite the first surface, at least one first opening that extends from the first surface to the second surface, and a first wall surface that faces the first opening, a second layer that includes a third surface that faces the second surface, a fourth surface that is located opposite the third surface, and multiple second openings that extend from the third surface to the fourth surface and that overlap the first opening in plan view, and a first intermediate layer that is located between at least the second surface and the third surface. The first layer contains silicon. The second layer contains a resin material. The first wall surface includes multiple recessed portions that are arranged in a thickness direction of the first layer.

### TECHNICAL FIELD

An embodiment of the present disclosure relates to a mask and a method of manufacturing a mask.

### BACKGROUND ART

A vapor deposition method is known as a method of forming a precise pattern. In the vapor deposition method, a mask that includes an opening is first combined with a substrate. Subsequently, a vapor deposition material is attached to the substrate via the opening of the mask. This enables a vapor deposition layer that contains the vapor deposition material to be formed on the substrate in a pattern that corresponds to the pattern of the opening of the mask. For example, the vapor deposition method is used as a method of forming pixels of an organic EL display device.

For example, PTL 1 discloses an aspect in which a mask device that includes a frame and a mask that is joined to the frame with a tension applied to the mask is used. The frame and the mask are composed of an iron alloy that contains nickel.

For example, PTL 2 discloses a vapor deposition mask that includes a metal mask that includes a slit and a resin mask that is stacked on the metal mask and that includes an opening portion that overlaps the slit. The resin mask is composed of a resin material such as polyimide resin. The metal mask is joined to a frame with a tension applied to the metal mask.

For example, PTL 3 rises an issue about a bend in the mask and a position shift of the vapor deposition layer. In PTL 3, a mask that is composed of a silicon substrate is proposed to solve the issue.

### CITATION LIST

### Patent Literature

PTL 1: Japanese Unexamined Patent Application Publication No. 2013-49889
PTL 2: Japanese Unexamined Patent Application Publication No. 2013-163864
PTL 3: Japanese Unexamined Patent Application Publication No. 2001-185350

### SUMMARY OF INVENTION

As the thickness of the silicon substrate decreases, the precision of the vapor deposition layer that is formed on the substrate increases. As the thickness of the silicon substrate decreases, the mask is more likely to be damaged.

It is an object of an embodiment of the present disclosure to provide a mask and a method of manufacturing of a mask that can effectively solve the issue.

A mask according to an embodiment of the present disclosure may include a first layer that includes a first surface, a second surface that is located opposite the first surface, at least one first opening that extends from the first surface to the second surface, and a first wall surface that faces the first opening, a second layer that includes a third surface that faces the second surface, a fourth surface that is located opposite the third surface, and multiple second openings that extend from the third surface to the fourth surface and that overlap the first opening in plan view, and a first intermediate layer that is located between at least the second surface and the third surface. The first layer may contain silicon. The second layer may contain a resin material. The first wall surface may include multiple recessed portions that are arranged in a thickness direction of the first layer.

According to an embodiment of the present disclosure, a mask can be inhibited from being damaged when the mask that contains silicon is moved.

### BRIEF DESCRIPTION OF DRAWINGS

FIG. 1 is a plan view of an example of an organic device.

FIG. 2 illustrates an example of a vapor deposition apparatus that includes a mask.

FIG. 3A is a plan view of an example of the mask when viewed from a position in front of an entrance surface.

FIG. 3B is a plan view of a modification to the mask when viewed from a position in front of the entrance surface.

FIG. 3C is a plan view of a modification to the mask when viewed from a position in front of the entrance surface.

FIG. 4 is a plan view of an example of the mask when viewed from a position in front of an exit surface.

FIG. 5A is a sectional view of the mask taken along a line V-V in FIG. 3A.

FIG. 5B is a sectional view of an example of an effective region.

FIG. 6 is an enlarged sectional view of a first wall surface of a first layer.

FIG. 7 is an enlarged sectional view of a portion that is surrounded by a one-dot chain line that is designated by using a reference sign of VII in FIG. 5A.

FIG. 8 is an enlarged sectional view of a portion that is surrounded by using a one-dot chain line that is designated by using a reference sign of VIII in FIG. 5A.

FIG. 9 is a sectional view of an example of a method of manufacturing a mask according to a first embodiment.

FIG. 10 is a sectional view of an example of the method of manufacturing the mask according to the first embodiment.

FIG. 11 is a sectional view of an example of the method of manufacturing the mask according to the first embodiment.

FIG. 12 is a sectional view of an example of the method of manufacturing the mask according to the first embodiment.

FIG. 13 is a sectional view of an example of a method of forming a first opening in the first layer.

FIG. 14 is a sectional view of an example of the method of forming the first opening in the first layer.

FIG. 15 is a sectional view of an example of the method of forming the first opening in the first layer.

FIG. 16 is a sectional view of an example of the method of forming the first opening in the first layer.

FIG. 17 is a sectional view of an example of the method of manufacturing the mask according to the first embodiment.

FIG. 18 is a sectional view of an example of the method of manufacturing the mask according to the first embodiment.

FIG. 19 is a sectional view of an example of a method of manufacturing a mask according to a second embodiment.

FIG. 20 is a sectional view of an example of a mask according to a third embodiment.

FIG. 21 is a sectional view of an example of a method of manufacturing the mask according to the third embodiment.

FIG. 22 is a sectional view of an example of the method of manufacturing the mask according to the third embodiment.

FIG. 23 is a sectional view of an example of the method of manufacturing the mask according to the third embodiment.

FIG. 24 is a sectional view of an example of the method of manufacturing the mask according to the third embodiment.

FIG. 25 is a sectional view of an example of a mask according to a fourth embodiment.

FIG. 26 is a sectional view of an example of a mask according to a fifth embodiment.

FIG. 27 is a sectional view of an example of a method of manufacturing the mask according to the fifth embodiment.

FIG. 28 is a sectional view of an example of the method of manufacturing the mask according to the fifth embodiment.

FIG. 29 is a sectional view of an example of the method of manufacturing the mask according to the fifth embodiment.

FIG. 30 is a sectional view of an example of the method of manufacturing the mask according to the fifth embodiment.

FIG. 31 is a sectional view of an example of a mask according to a sixth embodiment.

FIG. 32 is a sectional view of an example of a method of manufacturing the mask according to the sixth embodiment.

FIG. 33 is a sectional view of an example of a mask according to a seventh embodiment.

FIG. 34 is a sectional view of an example of a mask according to an eighth embodiment.

FIG. 35 is a sectional view of an example of a method of manufacturing the mask according to the eighth embodiment.

FIG. 36 is a sectional view of an example of the method of manufacturing the mask according to the eighth embodiment.

FIG. 37 is a plan view of an example of a mask according to a ninth embodiment.

FIG. 38 is a plan view of an example of the mask according to the ninth embodiment.

FIG. 39 is a plan view of an example of the mask according to the ninth embodiment.

FIG. 40 is a plan view of an example of the mask according to the ninth embodiment.

FIG. 41 illustrates an example of a device that includes an organic device.

FIG. 42 is a sectional view of an example of the first opening according to an eleventh embodiment.

FIG. 43 is a sectional view of an example of the first opening near the first surface of the first layer.

FIG. 44 is a sectional view of an example of the first opening near the second surface of the first layer.

FIG. 45 illustrates an example of the reason why an interval of recessed portions is non-uniform.

FIG. 46 illustrates an example of the reason why the interval of the recessed portions is non-uniform.

FIG. 47 illustrates an example of the reason why the interval of the recessed portions is non-uniform.

### DESCRIPTION OF EMBODIMENTS

The structure of a mask according to an embodiment and a method of manufacturing the mask will now be described in detail with reference to the drawings. The embodiment described later is an example of an embodiment of the present disclosure, and the present disclosure is not interpreted so as to be limited only to the embodiment. In the present specification, words such as a “plate”, a “base material”, a “sheet”, and a “film” are not distinguished from each other only based on different names. For example, the “plate” has a concept that includes a member that can be referred to as a sheet or a film. A “surface” means a surface of a target member in a plane direction when the target member is overall and comprehensively viewed. A normal direction means the direction of a normal to a surface of a member. Words such as “parallel” and “perpendicular” and the values of a length and an angle that specify shapes, geometrical conditions, and the degree of these and that are used in the present specification, for example, are not limited by strict meaning but are interpreted to an extent that the same function can be expected.

In the case where multiple candidates of the upper limit and multiple candidates of the lower limit regarding a parameter are taken in the present specification, the numeral range of the parameter may include a combination of a freely selected one of the candidates of the upper limit and a freely selected one of the candidates of the lower limit. For example, the case of the description that “for example, a parameter B is A1 or more, may be A2 or more, or may be A3 or more. For example, the parameter B is A4 or less, may be A5 or less, or may be A6 or less” is considered. In this case, the numeral range of the parameter B may be A1 or more and A4 or less, may be A1 or more and A5 or less, may be A1 or more and A6 or less, may be A2 or more and A4 or less, may be A2 or more and A5 or less, may be A2 or more and A6 or less, may be A3 or more and A4 or less, may be A3 or more and A5 or less, or may be A3 or more and A6 or less.

In some cases where a component such as a member or a region is “on” or “under”, “on an upper side of” or “on a lower side of”, or “above” or “below” another component such as another member or another region in the present specification and the drawings, the cases include a case where the component is in direct contact with the other component unless there is a particular description. The cases also include a case where another component is between the component and the other component, that is, a case where the component and the other component are indirectly connected to each other. As for the words “on”, “upper side”, and “above”, or “under”, “lower side”, and “below”, an up-down direction may be reversed unless there is a particular description.

In the present specification and the drawings, like portions or portions that have the same function are designated by like reference characters or similar reference characters unless there is a particular description, and a duplicated description for these is omitted in some cases. For convenience of description, the ratio of dimensions in the drawings differs from an actual ratio, and an illustration of a portion of a component is omitted in the drawings in some cases.

In the present specification and the drawings, an embodiment of the present disclosure may be combined with another embodiment or a modification so as not to be inconsistent unless there is a particular description. Other embodiments may be combined with each other so as not to be inconsistent, and another embodiment and a modification may be combined with each other so as not to be inconsistent. Modifications may be combined with each other so as not to be inconsistent.

In the case where multiple steps related to a method such as a manufacturing method are disclosed in the present specification and the drawings, another step that is not disclosed may be performed between the disclosed steps unless there is a particular description. The order of the disclosed steps is freely determined so as not to be inconsistent.

In the drawings referred according to the present embodiment, like portions or portions that have the same function are designated by like reference signs or similar reference signs, and a duplicated description for these is omitted in some cases. For convenience of description, the ratio of dimensions in the drawings differs from an actual ratio, and an illustration of a portion of a component is omitted in the drawings in some cases.

In an example described according to an embodiment of the present specification, a mask is used to form an organic layer or an electrode on a substrate when an organic EL display device is manufactured. However, the use of the mask is not particularly limited, and the present embodiment can be used for masks that are used in various ways. For example, the mask according to the present embodiment may be used to form a layer such as an organic layer or an electrode of a device that displays or projects an image or a picture for expressing virtual reality, so-called VR, or augmented reality, so-called AR. In addition, the mask according to the present embodiment may be used to form a layer of a display device other than an organic EL display device such as an electrode of a liquid-crystal display device. In addition, the mask according to the present embodiment may be used to form a layer of an organic device other than a display device such as an organic layer or an electrode of a pressure sensor.

A mask according to a first aspect of the present disclosure includes a first layer that includes a first surface, a second surface that is located opposite the first surface, at least one first opening that extends from the first surface to the second surface, and a first wall surface that faces the first opening, a second layer that includes a third surface that faces the second surface, a fourth surface that is located opposite the third surface, and multiple second openings that extend from the third surface to the fourth surface and that overlap the first opening in plan view, and a first intermediate layer that is located between at least the second surface and the third surface. The first layer contains silicon. The second layer contains a resin material. The first wall surface includes multiple recessed portions that are arranged in a thickness direction of the first layer.

As for a second aspect of the mask according to the first aspect described above, some of the multiple recessed portions close to the first surface may be arranged in the thickness direction in a first period, and some of the multiple recessed portions close to the second surface may be arranged in the thickness direction in a second period shorter than the first period.

As for a third aspect of the mask according to the first aspect or the second aspect described above, some of the multiple recessed portions close to the first surface may have a first depth, and some of the multiple recessed portions close to the second surface may have a second depth less than the first depth.

As for a fourth aspect of the mask according to any one of the first aspect described above to the third aspect described above, the first intermediate layer may include a first intermediate wall surface that is located outside a contour of the first opening on the second surface.

As for a fifth aspect of the mask according to any one of the first aspect described above to the fourth aspect described above, the first intermediate layer may include a first intermediate layer that has a thickness of 1 μm or less.

As for a sixth aspect of the mask according to any one of the first aspect described above to the fifth aspect described above, a second intermediate layer that is located on the third surface of the second layer and that has a thickness of 1 μm or more may be further included.

As for a seventh aspect of the mask according to any one of the first aspect described above to the sixth aspect described above, the first layer may include a plurality of the first openings, an inner region that is located between the first openings adjacent to each other in plan view, and an outer region that is located between an outer edge of the first layer and the first openings in plan view.

As for an eighth aspect of the mask according to the seventh aspect described above, a thickness of the inner region may be less than a thickness of the outer region.

As for a ninth aspect of the mask according to any one of the first aspect described above to the eighth aspect described above, a thickness of the second layer may be less than a thickness of the first layer, and a thickness of the first intermediate layer may be less than a thickness of the second layer. As for a tenth aspect of the mask according to any one of the first aspect described above to the ninth aspect described above, the first wall surface may include a tapered surface that extends outward as a position is nearer to the first surface.

As for an eleventh aspect of the mask according to any one of the first aspect described above to the tenth aspect described above, a stress adjustment layer that is located on the first surface may be further included.

As for a twelfth aspect of the mask according to any one of the first aspect described above to the eleventh aspect described above, the second layer may contain polyimide.

A method of manufacturing a mask according to a thirteenth aspect of the present disclosure includes a step of preparing a multilayer body including a first layer that includes a first surface and a second surface that is located opposite the first surface, a second layer that includes a third surface that faces the second surface and a fourth surface that is located opposite the third surface, and a first intermediate layer that is located between the second surface and the third surface, a step of partly forming a resist layer on the first surface, a first processing step of forming a first opening in the first layer by etching the first layer from the first surface, and a second processing step of forming multiple second openings in the second layer.

A method of manufacturing a mask according to a fourteenth aspect of the present disclosure includes a step of preparing a first layer that includes a first surface and a second surface that is located opposite the first surface, a step of partly forming a resist layer on the second surface, a first processing step of forming a first opening in the first layer by etching the first layer from the second surface, and a step of joining a second layer that includes a third surface that faces the second surface and a fourth surface that is located opposite the third surface to the first layer, and a second processing step of forming multiple second openings in the second layer. The mask includes a first intermediate layer that is located between the second surface and the third surface.

As for a fifteenth aspect of the method of manufacturing the mask according to the thirteenth aspect described above or the fourteenth aspect described above, the first processing step may include a dry etching step and a protection coating formation step that are alternately repeated.

As for a sixteenth aspect of the method of manufacturing the mask according to any one of the thirteenth aspect described above to the fifteenth aspect described above, a step of removing the resist layer before the second processing step after the first processing step may be further included.

As for a seventeenth aspect of the method of manufacturing the mask according to any one of the thirteenth aspect described above to the sixteenth aspect described above, a step of removing the first intermediate layer that overlaps the first opening in plan view before the second processing step after the first processing step may be further included.

As for a eighteenth aspect of the method of manufacturing the mask according to any one of the thirteenth aspect described above to the sixteenth aspect described above, a step of removing the first intermediate layer that overlaps the first opening in plan view after the second processing step may be included.

A method of manufacturing an organic device according to a nineteenth aspect of the present disclosure includes a step of forming an organic layer on a substrate by using a vapor deposition method in which the mask according to any one of the first aspect described above to the twelfth aspect described above is used.

### First Embodiment

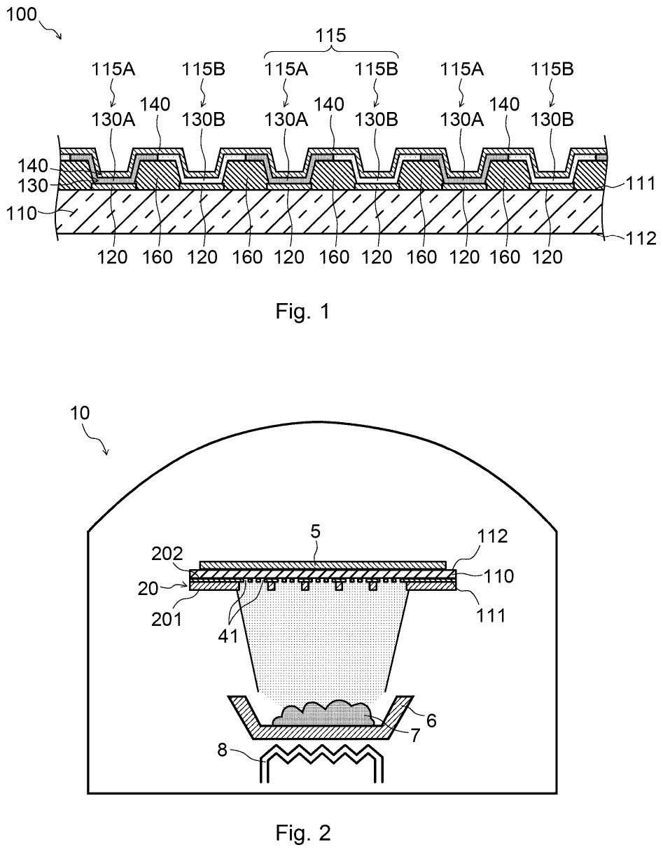

A first embodiment will be described with reference to FIG. 1 to FIG. 18. An organic device 100 that includes an organic layer that is formed by using a mask will now be described. FIG. 1 is a sectional view of an example of the organic device 100.

The organic device 100 includes a substrate 110 and multiple elements 115 that are arranged in an in-plane direction of the substrate 110. The substrate 110 includes a first surface 111 and a second surface 112 that is located opposite the first surface 111. The elements 115 are located on the first surface 111. Examples of the elements 115 are pixels. The substrate 110 may include two or more kind of the elements 115. For example, the substrate 110 may include first elements 115A and second elements 115B. The substrate 110 may include third elements although this is not illustrated. For example, the first elements 115A, the second elements 115B, and the third elements are red pixels, blue pixels, and green pixels.

The elements 115 may include first electrodes 120, organic layers 130 that are located on the first electrodes 120, and second electrodes 140 that are located on the organic layers 130.

The organic device 100 may include insulating layers 160 each of which is located between two of the first electrodes 120 adjacent to each other in plan view. For example, the insulating layers 160 contain polyimide. The insulating layers 160 may overlap end portions of the first electrodes 120. The words “in plan view” mean that an object is viewed in the normal direction of a surface of a plate member such as the substrate 110.

The substrate 110 may be an insulating member. Examples of the material of the substrate 110 can include rigid materials that are not flexible such as silicon, quartz glass, Pyrex (registered trademark) glass, and a synthetic quartz plate and flexible materials that are flexible such as a resin film, an optical resin plate, and thin glass. The substrate 110 may have the same planer shape as that of a silicon wafer that is used for manufacturing semiconductor. In this case, the substrate 110 can be processed by using a device that performs a semiconductor manufacturing step. For example, the first electrodes 120 and the insulating layers 160 can be formed on the substrate 110 by using the device that performs the semiconductor manufacturing step.

The elements 115 are configured to fulfill a function in a manner in which a voltage is applied between the first electrodes 120 and the second electrodes 140 or a current flows between the first electrodes 120 and the second electrodes 140. For example, in the case where the elements 115 are pixels of an organic EL display device, the elements 115 are capable of emitting light for forming a picture.

The first electrodes 120 contain a conductive material. For example, the first electrodes 120 contain metal, a conductive metal oxide or another conductive inorganic material. The first electrodes 120 may contain a transparent, conductive metal oxide such as an indium tin oxide.

The organic layers 130 contain an organic material. When the organic layers 130 are energized, the organic layers 130 can perform a function. The phrase “to be energized” means that a voltage is applied to the organic layers 130, or a current flows through the organic layers 130. Examples of the organic layers 130 can include light-emitting layers that emit light when being energized and layers the refractive index or the optical transmittance of which changes when being energized. The organic layers 130 may contain an organic semiconductor material.

As illustrated in FIG. 1, the organic layers 130 may include first organic layers 130A and second organic layers 130B. The first organic layers 130A are included in the first elements 115A. The second organic layers 130B are included in the second elements 115B. The organic layers 130 may include third organic layers that are included in the third elements although these are not illustrated. For example, the first organic layers 130A, the second organic layers 130B, and the third organic layers are red light-emitting layers, blue light-emitting layers, and green light-emitting layers.

When a voltage is applied between the first electrodes 120 and the second electrodes 140, the organic layers 130 that are located therebetween are driven. In the case where the organic layers 130 are light-emitting layers, light is emitted from the organic layers 130, and the light exits from the second electrodes 140 or the first electrodes 120 to the outside.

The organic layers 130 may further include a hole injection layer, a hole transport layer, an electron transport layer, an electron injection layer, and another layer.

The second electrodes 140 may contain a conductive material such as metal. Examples of the material of the second electrodes 140 can include platinum, gold, silver, copper, iron, tin, chromium, aluminum, indium, lithium, sodium, potassium, calcium, magnesium, chromium, carbon, and alloys of these. As illustrated in FIG. 1, the second electrodes 140 may extend across two of the organic layers 130 adjacent to each other in plan view.

A method of forming the organic layers 130 on the substrate 110 by using the vapor deposition method will now be described. FIG. 2 illustrates a vapor deposition apparatus 10. The vapor deposition apparatus 10 performs a vapor deposition process in which a vapor deposition material is deposited on an object.

As illustrated in FIG. 2, the vapor deposition apparatus 10 may include a vapor deposition source 6, a heater 8, and a mask 20 therein. The vapor deposition apparatus 10 may further include an exhaust unit for creating a vacuum atmosphere in the vapor deposition apparatus 10. An example of the vapor deposition source 6 is a crucible. The vapor deposition source 6 contains a vapor deposition material 7 such as an organic material or a metal material. The heater 8 heats the vapor deposition source 6 and vaporizes the vapor deposition material 7 in the vacuum atmosphere.

The mask 20 includes an entrance surface 201, an exit surface 202, and second openings 41. The entrance surface 201 faces the vapor deposition source 6. The exit surface 202 is located opposite the entrance surface 201. The exit surface 202 faces the first surface 111 of the substrate 110. The vapor deposition material 7 that enters the mask 20 via the entrance surface 201 partly passes through the second openings 41 and exits via the exit surface 202. The vapor deposition material 7 that exits via the exit surface 202 is attached to the first surface 111 of the substrate 110. The exit surface 202 of the mask 20 may be in contact with the first surface 111 of the substrate 110.

As illustrated in FIG. 2, the vapor deposition apparatus 10 may include a magnet 5 that is disposed on the second surface 112 of the substrate 110. In the case where the mask 20 contains a metal material, the magnet 5 is capable of attracting the mask 20 toward the substrate 110 due to magnetic force. This enables a gap between the mask 20 and the substrate 110 to be reduced or enables the gap to be eliminated. This enables shadow to be inhibited from occurring at a vapor deposition step. In the present application, the shadow means a phenomenon in which the thicknesses of the organic layers 130 that are formed near wall surfaces of the second openings 41 are less than the thicknesses of the organic layers 130 at the centers of the second openings 41. The shadow occurs, for example, due to the vapor deposition material 7 that is attached to a wall surface of the mask 20 or the vapor deposition material 7 that enters the gap between the mask 20 and the substrate 110.

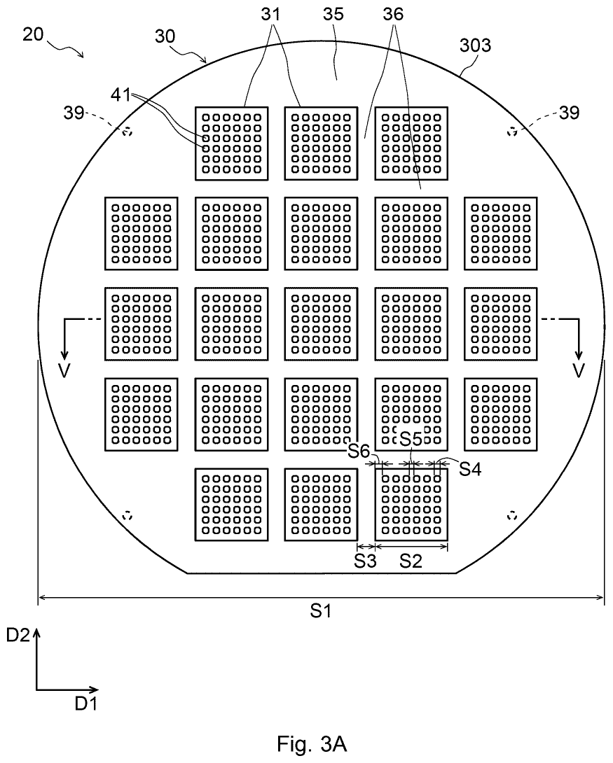

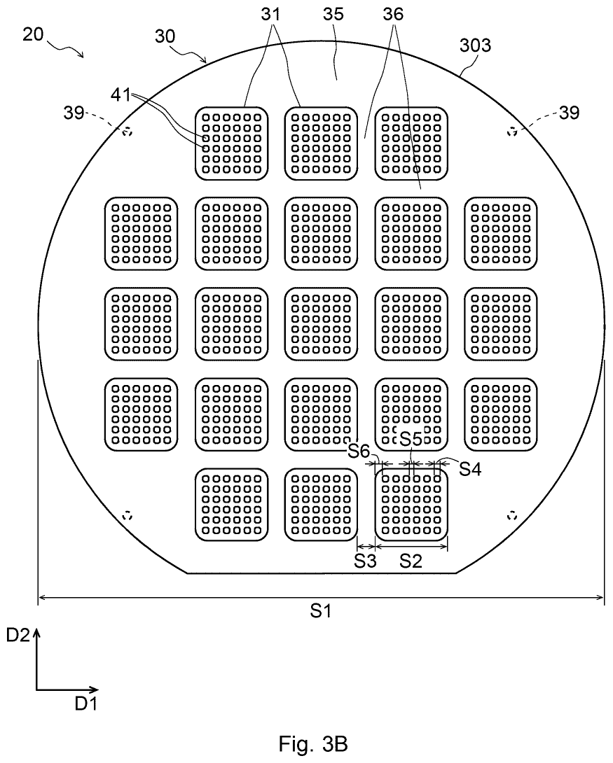

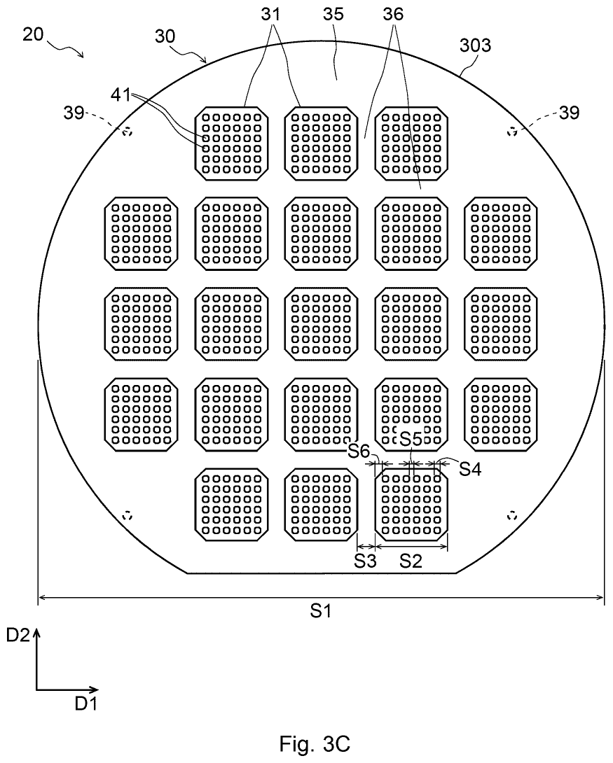

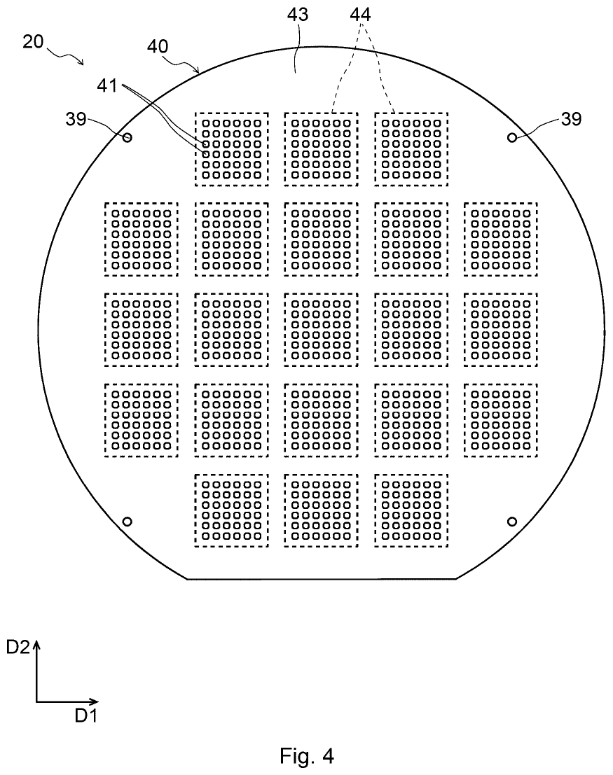

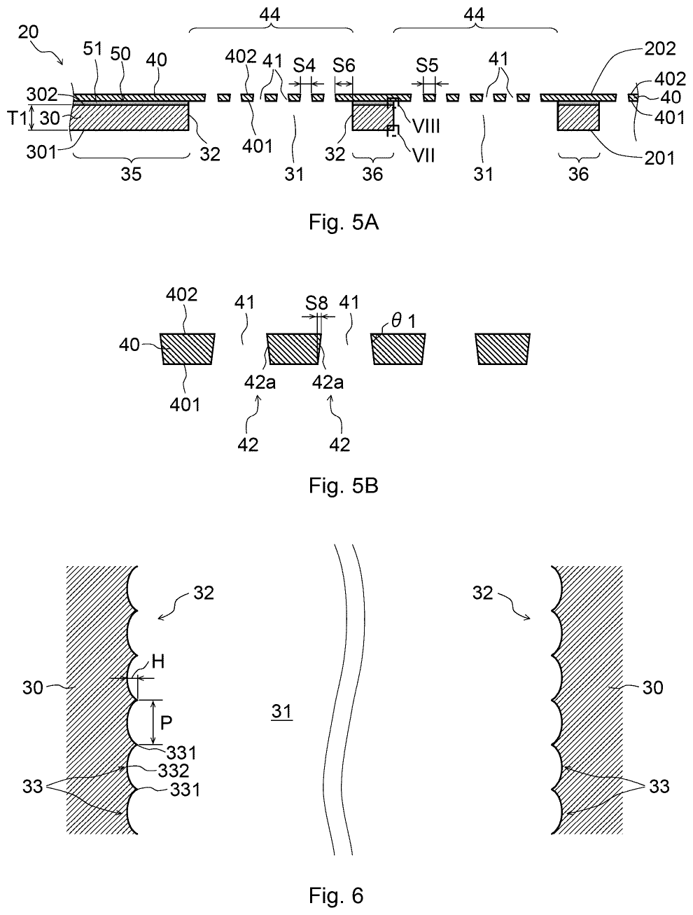

The mask 20 will now be described in detail. FIG. 3A is a plan view of an example of the mask 20 when viewed from a position in front of the entrance surface 201. FIG. 4 is a plan view of an example of the mask 20 when viewed from a position in front of the exit surface 202. FIG. 5A is a sectional view of the mask 20 taken along a line V-V in FIG. 3A.

As illustrated in FIG. 5A, the mask 20 includes a first layer 30, an intermediate layer 50, and a second layer 40 that are arranged in order from the entrance surface 201 to the exit surface 202. The first layer 30 contains silicon or a silicon compound. An example of the silicon compound is silicon carbide (SIC). The second layer 40 contains a resin material. The layers will be described below.

The first layer 30 includes a first surface 301, a second surface 302, first openings 31, and first wall surfaces 32. The first surface 301 may form the entrance surface 201. The second surface 302 is located opposite the first surface 301.

The first openings 31 extend from the first surface 301 to the second surface 302. As illustrated in FIG. 3A, the first layer 30 may include the multiple first openings 31. The multiple first openings 31 may be arranged in a first direction D1 and a second direction D2. The second direction D2 may be perpendicular to the first direction D1.

The first openings 31 may correspond to a single screen of an organic EL display device. The mask 20 illustrated in FIG. 3A enables the pattern of an organic layer that corresponds to multiple screens to be simultaneously formed on the substrate 110. As illustrated in FIG. 3A, the first openings 31 may have a rectangular contour in plan view.

FIG. 3B and FIG. 3C are plan views of other examples of the mask 20. As illustrated in FIG. 3B, corner portions of the contour of each first opening 31 may include curved portions. As illustrated in FIG. 3C, the contour of the first opening 31 may have an octagonal shape. In the examples illustrated in FIG. 3B and FIG. 3C, stress can be inhibited from being concentrated on the corner portions in the case where the stress is applied to the contour of the first opening 31. For this reason, the first layer 30 can be inhibited from being damaged.

The first wall surfaces 32 are surfaces of the first layer 30 that face the first openings 31. In the example illustrated in FIG. 3A, the first wall surfaces 32 extend in the normal direction of the first surface 301.

As illustrated in FIG. 3A, a region of the first layer 30 in which the first openings 31 are not formed may be divided into an outer region 35 and an inner region 36. The inner region 36 is located between two of the first openings 31 adjacent to each other in plan view. The outer region 35 is located between an outer edge 303 of the first layer 30 and the first openings 31 of in plan view. As illustrated in FIG. 3A, the inner region 36 may extend in the first direction D1 and the second direction D2.

As illustrated in FIG. 3A and FIG. 4, the first layer 30 may include alignment marks 39. For example, the alignment marks 39 are formed on the second surface 302. The alignment marks 39 may be formed on the first surface 301. For example, the alignment marks 39 are used to adjust the relative position of the substrate 110 with respect to the mask 20. In the case where the substrate 110 has properties that enable visible light to pass therethrough, the alignment marks 39 can be visually recognized through the substrate 110.

As illustrated in FIG. 3A and FIG. 4, the alignment marks 39 may have a circular contour in plan view. The alignment marks 39 may include a contour that has another shape other than a circular shape such as a rectangular shape or a cross shape although this is not illustrated. The alignment marks 39 may be located in the outer region 35 or may be located in the inner region 36.

The shapes of the alignment marks 39 in sectional view are freely determined.

For example, the alignment marks 39 may include recessed portions that are located on the first surface 301 or the second surface 302. The alignment marks 39 may include holes that extend from the first surface 301 to the second surface 302. The recessed portions and the holes may be formed by etching the first surface 301 or the second surface 302. The recessed portions and the holes may be formed in a manner in which the first surface 301 or the second surface 302 is irradiated with a laser.

For example, the alignment marks 39 may include layers that are located on the first surface 301 or the second surface 302. The layers are composed of a material that differs from that of the first layer 30. In the case where the layers are formed on the second surface 302, the second layer 40 and the intermediate layer 50 may include holes that overlap the layers. This enables the visual recognition of the alignment marks 39 to be improved.

The alignment marks 39 may be formed on a layer other than the first layer 30.

The first layer 30 contains silicon or a silicon compound as described above. For example, the first layer 30 is manufactured by processing a silicon wafer. As illustrated in FIG. 3A, the outer edge 303 of the first layer 30 may include a straight portion. The straight portion is also referred to as an orientation flat. The outer edge 303 may include a cutout although this is not illustrated. The cutout is also referred to as a notch. The orientation flat and the notch represent the crystal orientation of the silicon wafer.

For example, the maximum dimension S1 of the first layer 30 in plan view is 100 mm or more, may be 150 mm or more, or may be 200 mm or more. For example, the dimension S1 is 500 mm or less, may be 400 mm or less, or may be 300 mm or less.

For example, the dimension S2 of each first opening 31 in a direction in which each first opening 31 is arranged is 5 mm or more, may be 10 mm or more, or may be 20 mm or more. For example, the dimension S2 is 100 mm or less, may be 50 mm or less, or may be 30 mm or less.

For example, an interval S3 between two of the first openings 31 in the direction in which the first openings 31 are arranged is 0.1 mm or more, may be 0.5 mm or more, or may be 1.0 mm or more. For example, the interval S3 is 20 mm or less, may be 15 mm or less, or may be 10 mm or less.

The thickness of the first layer 30 is defined as the maximum thickness T1 of the outer region 35. For example, the thickness T1 is 50 μm or more, may be 100 μm or more, or may be 200 μm or more. For example, the thickness T1 is 1000 μm or less, may be 800 μm or less, or may be 600 μm or less.

The second layer 40 will now be described. The second layer 40 includes a third surface 401, a fourth surface 402, and multiple second openings 41. The third surface 401 faces the second surface 302 of the first layer 30. The fourth surface 402 is located opposite the third surface 401.

The second openings 41 extend from the third surface 401 to the fourth surface 402. One of the second openings 41 corresponds to one of the organic layers 130. A group of the multiple second openings 41 that are regularly arranged corresponds to a single screen of an organic EL display device. As illustrated in FIG. 3A and FIG. 4, the group of the multiple second openings 41 that are regularly arranged may overlap one of the first openings 31 in plan view. Multiple groups of the second openings 41 are supported by the first layer 30 that is formed by processing a single member such as a silicon wafer.

The second layer 40 may be divided into a peripheral region 43 and an effective region 44. The peripheral region 43 overlaps the first layer 30 in plan view. The effective region 44 is a region in which the groups of the multiple second openings 41 that are regularly arranged are distributed.

FIG. 5B is a sectional view of an example of the effective region 44. The second layer 40 includes second wall surfaces 42 that face the second openings 41. As illustrated in FIG. 5B, the second wall surfaces 42 may include tapered surfaces 42a that are gradually separated from the centers of the second openings 41 as the positions are nearer to the third surface 401. The second wall surfaces 42 include the tapered surfaces 42a, and consequently, shadow can be inhibited from occurring near the second wall surfaces 42.

In FIG. 5B, a reference sign of S8 represents the width of each tapered surface 42a in a direction in which the second openings 41 are arranged. For example, the width S8 is 0.2 μm or more, may be 0.5 μm or more, or may be 1.0 μm or more. For example, the width S7 is 25 μm or less, may be 20 μm or less, or may be 10 μm or less.

In FIG. 5B, a reference sign of 01 represents an angle that is formed between each second wall surface 42 and the fourth surface 402. For example, the angle θ1 is 50° or more, may be 55° or more, or may be 60° or more. For example, the angle θ1 is less than 90°, may be 85° or less, or may be 80° or less.

The second layer 40 contains a resin material as described above. Examples of the resin material include polyimide resin, polyamide resin, polyamide imide resin, polyester resin, polyethylene resin, polyvinyl alcohol resin, polypropylene resin, polycarbonate resin, polystyrene resin, polyacrylonitrile resin, ethylene vinyl acetate copolymer resin, ethylene-vinyl alcohol copolymer resin, ethylene-methacrylic acid copolymer resin, polyvinyl chloride resin, polyvinylidene chloride resin, cellophane, and ionomer resin. The second layer 40 may be composed of a single resin layer or may include multiple resin layers.

The thickness of the second layer 40 is less than the thickness T1 of the first layer 30. For example, the thickness of the second layer 40 is 25 μm or less, may be 10 μm or less, or may be 5 μm or less. This enables shadow to be inhibited from occurring. For example, the thickness of the second layer 40 is 0.5 μm or more, may be 1.0 μm or more, or may be 2.0 μm or more. This enables the second layer 40 to be inhibited, for example, from having a defect such as a pinhole and from deforming.

For example, the dimension S4 of each second opening 41 in plan view is 1 μm or more, may be 2 μm or more, or may be 3 μm or more. For example, the dimension S4 is 25 μm or less, may be 10 μm or less, or may be 5 μm or less.

For example, an interval S5 between two of the second openings 41 in the direction in which the second openings 41 are arranged is 1 μm or more, may be 2 μm or more, or may be 3 μm or more. For example, the dimension S4 is 25 μm or less, may be 10 μm or less, or may be 5 μm or less.

Intervals S6 between the first wall surfaces 32 and the second openings 41 in plan view may be larger than the interval S5. This enables shadow to be inhibited from occurring at the second openings 41 close to the first wall surfaces 32.

The second layer 40 may include an alignment mark. The alignment mark of the second layer 40 may be formed separately from the alignment marks 39 of the first layer 30 or may be formed instead of the alignment marks 39 of the first layer 30.

The alignment mark of the second layer 40 may include a recessed portion that is located on the third surface 401 or the fourth surface 402. The alignment mark of the second layer 40 may include a hole that extends from the third surface 401 to the fourth surface 402. The recessed portion and the hole may be formed by etching the third surface 401 or the fourth surface 402. The recessed portion and the hole may be formed in a manner in which the third surface 401 or the fourth surface 402 is irradiated with a laser.

The intermediate layer 50 will now be described. The intermediate layer 50 includes a layer that provide a function to the first layer 30 or the second layer 40. For example, the intermediate layer 50 includes a first intermediate layer 51. In an example illustrated in FIG. 5A, the first intermediate layer 51 is located between the first layer 30 and the second layer 40.

The first intermediate layer 51 may function as a stopper layer that stops etching at a step of processing the first layer 30 by etching. Specifically, the first intermediate layer 51 has resistance against etchant for etching the first layer 30. The first intermediate layer 51 may contain aluminum, an aluminum alloy, titanium, or a titanium alloy. The first intermediate layer 51 may contain an inorganic compound such as a silicon oxide.

In the case where the first intermediate layer 51 is the stopper layer, the thickness of the first intermediate layer 51 is not particularly limited provided that the second layer 40 can be inhibited from being etched at the step of processing the first layer 30. For example, the thickness of the first intermediate layer 51 may be less than the thickness of the second layer 40 or may be equal to or greater than the thickness of the second layer 40. For example, the thickness of the first intermediate layer 51 is 5 nm or more, may be 50 nm or more, or may be 75 nm or more. For example, the thickness of the first intermediate layer 51 is 100 μm or less, may be 50 μm or less, may be 10 μm or less, may be 5 μm or less, may be 1 μm or less, or may be 150 nm or less. As the resistance of the first intermediate layer 51 against the etchant for the first layer 30 becomes greater, the thickness of the first intermediate layer 51 can be further decreased. The thickness of the first intermediate layer 51 is particularly preferably 1 μm or less.

The intermediate layer 50 may include a layer that fulfills a function of joining the first layer 30 and the second layer 40 to each other. For example, the first intermediate layer 51 may be a joining layer that contains an adhesive. For example, the thickness of the joining layer is 0.1 μm or more, may be 0.2 μm or more, or may be 0.5 μm or more. For example, the thickness of the joining layer is 3 μm or less, may be 2 μm or less, or may be 1 μm or less.

The intermediate layer 50 is preferably located so as not to overlap the second openings 41 in plan view. This enables shadow to be inhibited from occurring due to the intermediate layer 50.

The first intermediate layer 51 may include an alignment mark. The alignment mark of the first intermediate layer 51 may be formed separately from the alignment mark of the first layer 30 or the second layer 40 or may be formed instead of the alignment mark of the first layer 30 or the second layer 40.

The thicknesses of the layers, the intervals, and the dimensions of components, for example, can be measured in a manner in which an image of a section of the mask 20 is observed by using a scanning electron microscope.

The structure of the first wall surfaces 32 of the first layer 30 will now be described in detail. FIG. 6 is an enlarged sectional view of the first wall surfaces 32.

As illustrated in FIG. 6, the first wall surfaces 32 include multiple recessed portions 33 that are arranged in the thickness direction of the first layer 30. The multiple recessed portions 33 are produced in the case where the first openings 31 are formed by alternately repeating a dry etching step and a protection coating formation step as described later. The recessed portions 33 include top portions 331 and bottom portions 332. The top portions 331 are located at the innermost positions on the recessed portions 33. The bottom portions 332 are located at the outermost positions on the recessed portions 33. The word “inner” represents a direction toward the center of each first opening 31 in the in-plane direction of the first surface 301. The word “outer” represents a direction away from the center of each first opening 31 in the in-plane direction of the first surface 301.

In FIG. 6, a reference sign of P represents the period of the recessed portions 33 in the thickness direction of the first layer 30. The period P is equal to an interval between two of the top portions 331 adjacent to each other in the thickness direction of the first layer 30. For example, the period P is 100 nm or more, may be 300 nm or more, may be 500 nm or more, may be 1 μm or more, or may be 1.5 μm or more. For example, the period P is 10 μm or less, may be 7 μm or less, may be 5 μm or less, may be 3 μm or less, may be 2 μm or less, or may be 1 μm or less.

In FIG. 6, a reference sign of H represents the depth of each recessed portion 33. The depth H is equal to a distance between the top portions 331 and the bottom portions 332 in the in-plane direction of the first surface 301. For example, the depth H is 1 nm or more, may be 3 nm or more, or may be 5 nm or more. For example, the depth H is 3 μm or less, may be 2 μm or less, or may be 1 μm or less.

The areas of the first wall surfaces 32 that include the recessed portions 33 are larger than those in the case where the wall surfaces are flat. Accordingly, including the recessed portions 33 in the first wall surfaces 32 contributes to an improvement in adhesion of the vapor deposition material 7 to the first wall surfaces 32. For this reason, for example, the vapor deposition material 7 that is attached to the first wall surfaces 32 once can be inhibited from being separated from the first wall surfaces 32 during the vapor deposition step. This enables an unnecessary lump of the vapor deposition material 7 to be inhibited from floating in the vapor deposition apparatus 10. The floating lump of the vapor deposition material 7 can be attached to the mask 20 or the substrate 110 again, and accordingly, the vapor deposition material 7 is preferably inhibited from being separated.

FIG. 7 is an enlarged sectional view of a portion that is surrounded by a one-dot chain line designated by using a reference sign of VII in FIG. 5A. As illustrated in FIG. 7, the multiple recessed portions 33 close to the first surface 301 are arranged in the thickness direction of the first layer 30 in a first period P1. The recessed portions 33 have a first depth H1.

FIG. 8 is an enlarged sectional view of a portion that is surrounded by a one-dot chain line designated by using a reference sign of VIII in FIG. 5A. As illustrated in FIG. 8, the multiple recessed portions 33 close to the second surface 302 are arranged in the thickness direction of the first layer 30 in a second period P2. The recessed portions 33 have a second depth H2.

As illustrated in FIG. 7 and FIG. 8, the second period P2 may be shorter than the first period P1. The second depth H2 may be less than the first depth H1. In this case, the areas of the first wall surfaces 32 close to the second surface 302 are smaller than the areas of the first wall surfaces 32 close to the first surface 301. In other words, the areas of the first wall surfaces 32 close to the first surface 301 are larger than the areas of the first wall surfaces 32 close to the second surface 302. Consequently, the improvement in the adhesion of the vapor deposition material 7 to the first wall surfaces 32 is expected near the first surface 301.

For example, P2/P1 is 0.98 or less, may be 0.95 or less, or may be 0.90 or less. For example, P2/P1 is 0.10 or more, may be 0.20 or more, or may be 0.30 or more.

For example, H2/H1 is 0.98 or less, may be 0.95 or less, or may be 0.90 or less. For example, H2/H1 is 0.10 or more, may be 0.20 or more, or may be 0.30 or more.

The periods and depths of the recessed portions 33 can be measured in a manner in which an image of a section of the first layer 30 is observed by using the scanning electron microscope. A sample for observation can be obtained in a manner in which the first layer 30 is cut by a focused ion beam device. The first period P1 and the first depth H1 are calculated as the average values of the periods and depths of five recessed portions 33 that are arranged in a direction from the first surface 301 to the second surface 302. The second period P2 and the second depth H2 are calculated as the average values of the periods and depths of five recessed portions 33 that are arranged in a direction from the second surface 302 to the first surface 301. The period P is calculated as the average value of the first period P1 and the second period P2. The depth H is calculated as the average value of the first depth H1 and the second depth H2.

As illustrated in FIG. 8, the first intermediate layer 51 may include a first intermediate wall surface 52 that faces the first openings 31. The first intermediate wall surface 52 may overlap the second surface 302 of the first layer 30 in plan view. In other words, the first intermediate wall surface 52 may be located outside the contours of the first openings 31 on the second surface 302. The first intermediate wall surface 52 is formed due to side etching when the first intermediate layer 51 that overlaps the first openings 31 in plan view is removed by wet etching.

### (Method of Manufacturing Vapor Deposition Mask)

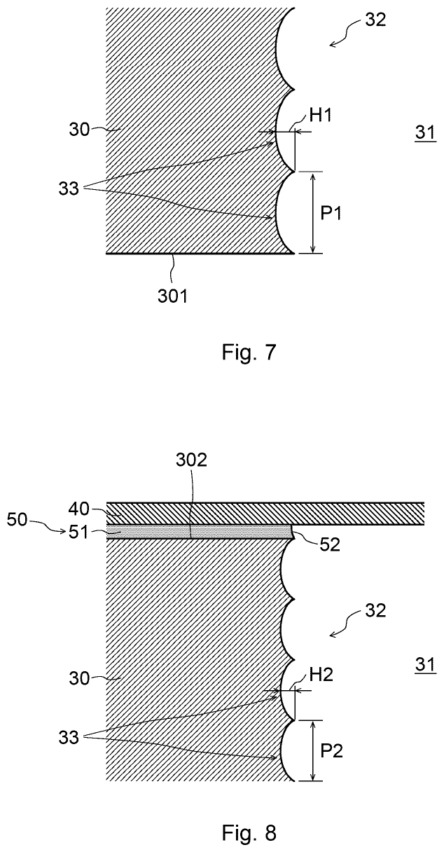

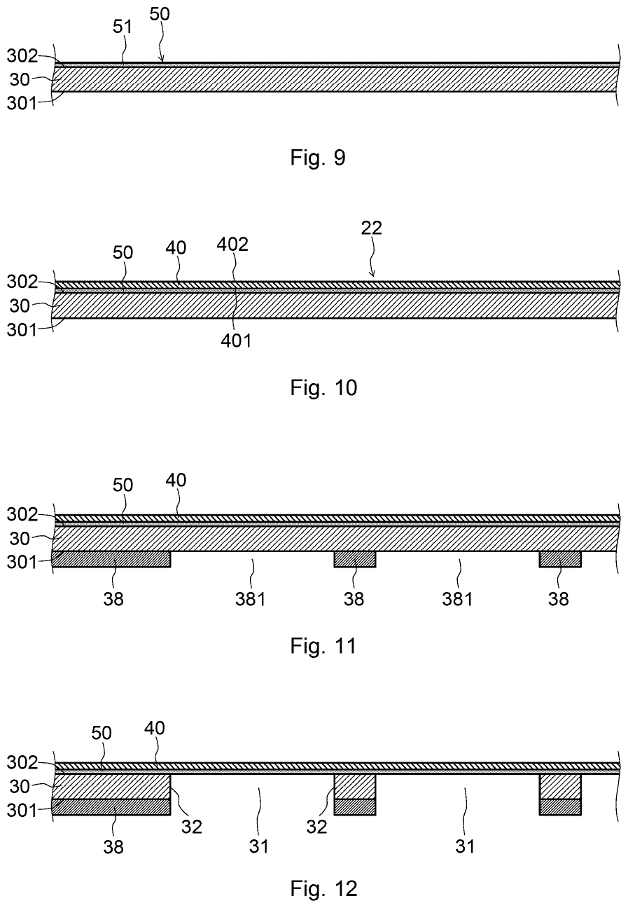

A method of manufacturing a vapor deposition mask according to the present embodiment will now be described with reference to FIG. 9 to FIG. 18. The first layer 30 is first prepared. The first layer 30 may be a silicon wafer. The first surface 301 and the second surface 302 of the first layer 30 may be polished into mirror surfaces. The arithmetic average roughness Ra of the first surface 301 and the second surface 302 may be 1.5 nm or less or may be 1.0 nm or less. For example, the plane orientations of the first surface 301 and the second surface 302 may be (100) and (110).

Subsequently, as illustrated in FIG. 9, the intermediate layer 50 is formed on the second surface 302 of the first layer 30. For example, the intermediate layer 50 includes the first intermediate layer 51. The intermediate layer 50 may be formed on the whole of the second surface 302. For example, the intermediate layer 50 may be formed by using a vacuum film formation method such as a spattering method.

Subsequently, as illustrated in FIG. 10, the second layer 40 is formed on the intermediate layer 50. This enables a multilayer body 22 that includes the first layer 30, the intermediate layer 50, and the second layer 40 to be obtained. The second layer 40 may be formed on the whole of the intermediate layer 50. For example, the second layer 40 may be formed by using a coating method such as a spin coating method.

A heating step of heating the second layer 40 may be performed after the material of the second layer 40 is coated on the intermediate layer 50. This enables the second layer 40 to be solidified. For example, the heating step is performed after polyamide acid that is a precursor of polyimide is coated on the intermediate layer 50, and consequently, an imidization reaction can occur. This enables the second layer 40 that contains polyimide to be formed. For example, a temperature at the heating step is 200° C. or more, or may be 300° C. or more. For example, the temperature at the heating step is 500° C. or less or may be 400° C. or less. For example, the time of the heating step is 10 minutes or more or may be 20 minutes or more. For example, the time of the heating step is 200 minutes or less or may be 100 minutes or less.

A pressing step of pressing the second layer 40 may be performed although this is not illustrated. For example, a surface of a substrate such as a silicon wafer or a glass wafer that differs from the first layer 30 may be pressed against the second layer 40. In the case where the surface of the substrate is flatter than the fourth surface 402 of the second layer 40, the pressing step enables the flatness of the fourth surface 402 to be improved. The surface of the substrate may have an uneven pattern. In this case, the pressing step enables the fourth surface 402 to have an uneven pattern. The pressing step may be performed before a step of heating the second layer 40.

The multilayer body 22 may include a protection layer that is located on the fourth surface 402 of the second layer 40 although this is not illustrated. For example, the protection layer contains the same material as the material of the first intermediate layer 51. The protection layer is formed on the fourth surface 402, and consequently, the fourth surface 402 can be inhibited from being etched at a first processing step described later. The protection layer may be removed at the same time the first intermediate layer 51 is removed.

Subsequently, as illustrated in FIG. 11, a resist formation step of partly forming a resist layer 38 on the first surface 301 of the first layer 30 is performed. Resist openings 381 that face the first openings 31 are formed in the resist layer 38.

The resist layer 38 may be photoresist. In this case, a liquid resist material is first coated on the first surface 301, and consequently the resist layer 38 is formed on the first surface 301. After coating, a step of heating the resist layer 38 may be performed. Subsequently, a photolithography process in which the resist layer 38 is exposed to light and is developed is performed. This enables the resist openings 381 to be formed in the resist layer 38.

The resist layer 38 may be a silicon oxide film that is partly formed on the first surface 301 although this is not illustrated. For example, the silicon oxide film is formed in a manner in which a thermal oxidation treatment is partly performed on the first surface 301. The silicon oxide film may be formed on the first layer 30 before the intermediate layer 50 and the second layer 40 are stacked on the first layer 30.

Subsequently, as illustrated in FIG. 12, the first processing step of forming the first openings 31 in the first layer 30 by etching the first layer 30 from the first surface 301 is performed. Etching at the first processing step may be dry etching in which etching gas is used. The etching gas is an example of the etchant described above. Since the intermediate layer 50 has resistance against the etchant, as illustrated in FIG. 12, etching can be inhibited from progressing up to the second layer 40.

The first processing step will be described in detail with reference to FIG. 13 to FIG. 16. In an example described herein, the first openings 31 are formed by deep reactive-ion etching.

As illustrated in FIG. 13, a step of dry etching the first layer 30 from the first surface 301 is first performed. For example, the etching gas is introduced into a chamber. A voltage is applied to a space in the chamber, and consequently, the etching gas is in the state of plasma. Radicals and ions in the plasma, for example, pass through the resist openings 381 and collide with the first surface 301, and as illustrated in FIG. 13, first holes 311 can be consequently formed in the first surface 301. An example of the etching gas is SF₆ gas.

Each first hole 311 includes a first wall surface 311a and a first bottom surface 311b. The first wall surface 311a may be located outside an end surface 38e of the resist layer 38. The time of the dry etching step, a gas flow rate, and the voltage, for example, are adjusted, and consequently, the position of the first wall surface 311a can be adjusted. For example, the time of the dry etching step performed once is 1 second or more or may be 2 seconds or more. For example, the time of the dry etching step performed once is 10 seconds or less or may be 5 seconds or less.

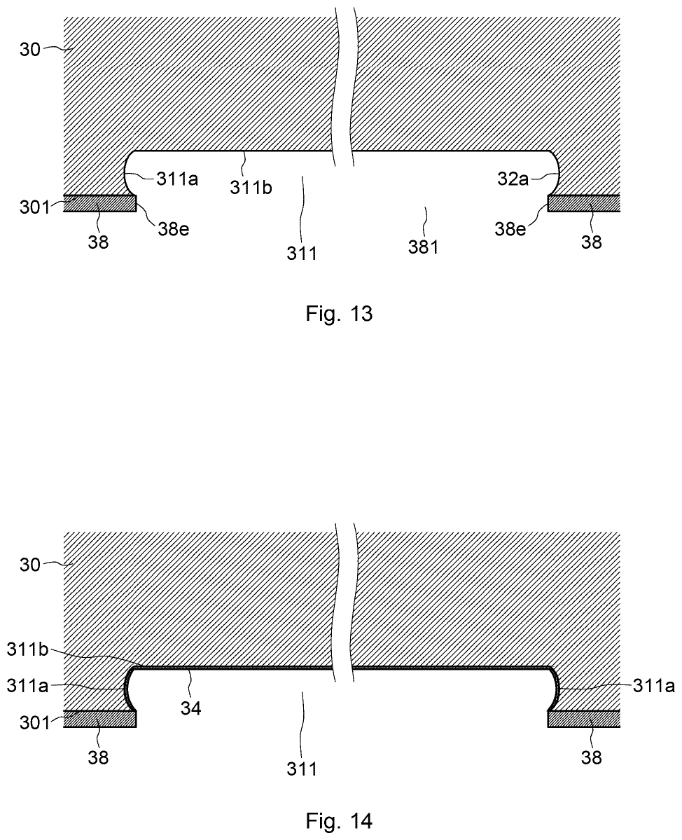

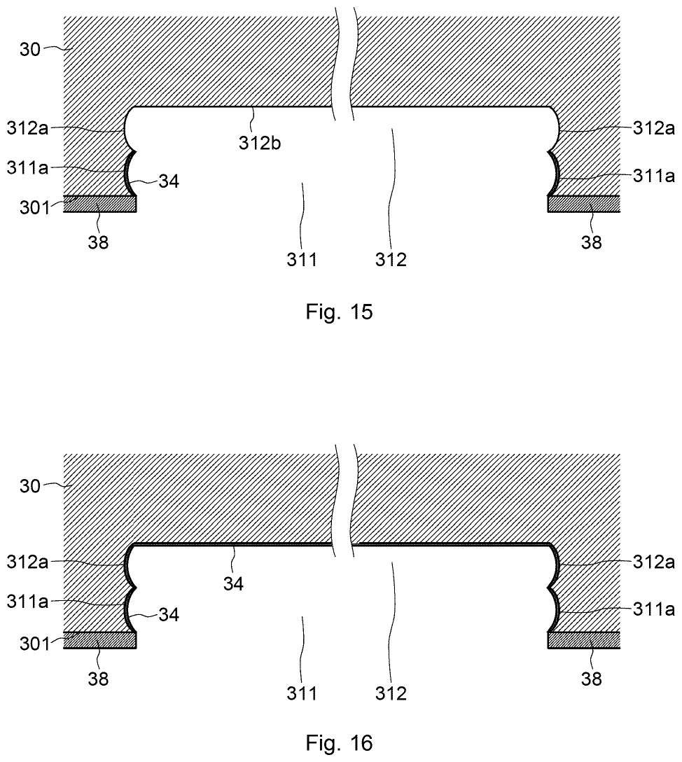

Subsequently, a protection coating formation step of forming protection coatings on the wall surfaces and the bottom surfaces of the holes is performed. Specifically, the gas that is introduced into the chamber is changed from the etching gas into material gas. An example of the material gas is C₄F₈ gas. A voltage is applied to the space in the chamber, and consequently, the material gas is in the state of plasma. Radicals in the plasma, for example, react at the first wall surface 311a and the first bottom surface 311b, and as illustrated in FIG. 14, a protection coating 34 can be consequently formed on each first wall surface 311a and each first bottom surface 311b.

Subsequently, the dry etching step at the second time is performed. The radicals and the ions in the plasma, for example, collide with the protection coating 34 on each first bottom surface 311b, and consequently, the protection coating 34 can be removed. Subsequently, the radicals and the ions in the plasma, for example, collide with the first bottom surface 311b, and as illustrated in FIG. 15, second holes 312 can be formed in the first bottom surface 311b.

Each second hole 312 includes a second wall surface 312a and a second bottom surface 312b. The position of the second wall surface 312a may be the same as the position of the first wall surface 311a in the in-plane direction of the first surface 301. The second wall surface 312a may be located outside or inside the first wall surface 311a although this is not illustrated. The time of the dry etching step, the gas flow rate, and the voltage, for example, are adjusted, and consequently, the position of the second wall surface 312a can be adjusted.

Subsequently, the protection coating formation step at the second time is performed. As illustrated in FIG. 16, this enables the protection coating 34 to be formed on each second wall surface 312a and each second bottom surface 312b.

The dry etching step and the protection coating formation step described above are alternately repeated until the first openings 31 reach the intermediate layer 50. This enables the first openings 31 that pass through from the first surface 301 to the second surface 302 to be formed. Since the intermediate layer 50 has resistance against the etching gas, the second layer 40 can be inhibited from being etched. For convenience of description, the example begins with the dry etching step but may begin with the protection coating formation step.

As holes are deeper, that is, the first openings 31 are nearer to the second surface 302, the etchant is more unlikely to reach the bottom surfaces of the holes. For this reason, in the case where etching conditions are constant, the sizes of the holes that are formed by performing the dry etching step once decrease as the positions are nearer to the second surface 302. As a result, as illustrated in FIG. 7 and FIG. 8, the second period P2 is shorter than the first period P1, and the second depth H2 is less than the first depth H1.

The sizes of the holes may be adjusted in a manner in which the etching conditions are adjusted depending on the positions of the holes.

For example, etching intensity or time may be increased as the first openings 31 are nearer to the second surface 302. This enables the second period P2 and the first period P1 to be inhibited from differing from each other. In addition, the second depth H2 and the first depth H1 can be inhibited from differing from each other. For example, the etching intensity increases, as the voltage and the flow rate and concentration of the etching gas, for example, increase.

In contrast, the etching intensity or the time may be decreased as the first openings 31 are nearer to the second surface 302. This enables the second period P2 and the first period P1 to differ from each other to a greater degree. In addition, the second depth H2 and the first depth H1 can be likely to differ from each other to a greater degree.

A protection coating removal step of removing the protection coating 34 may be performed after the first openings 31 reach the intermediate layer 50. For example, a protection coating processing liquid is supplied to the first openings 31 of the first layer 30. The multilayer body 22 may be immersed in a tank that stores the protection coating processing liquid. For example, the protection coating processing liquid contains hydrofluoroether.

A resist removal step of removing the resist layer 38 may be performed after the holes reach the intermediate layer 50. For example, a resist processing liquid is supplied to the first surface 301.

In the case where the resist layer 38 is photoresist, for example, the resist processing liquid contains N-methyl-2-pyrrolidone. The resist layer 38 may be removed in a manner in which the resist layer 38 is irradiated with oxygen plasma.

In the case where the resist layer 38 is a silicon oxide film, for example, the resist processing liquid contains hydrofluoric acid. The resist layer 38 may be removed by dry etching in which CF₄ gas is used.

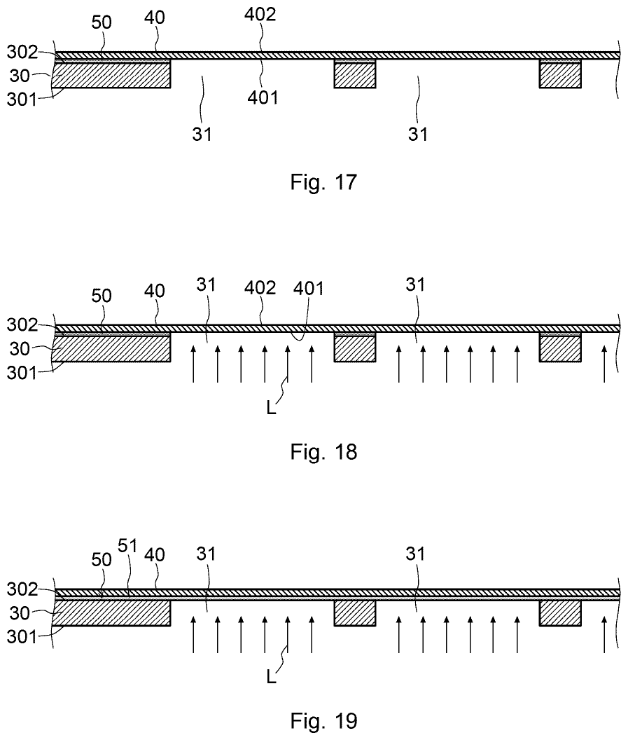

An intermediate layer removal step of removing the intermediate layer 50 may be performed after the first processing step. For example, etchant for the intermediate layer 50 is supplied to the first openings 31. As illustrated in FIG. 17, this enables the intermediate layer 50 that overlaps the first openings 31 in plan view to be removed. As illustrated in FIG. 8, the side etching that occurs at this time causes the first intermediate wall surface 52 that is located outside the contours of the first openings 31 on the second surface 302 to be formed. The intermediate layer 50 may be etched by dry etching in which fluorine gas, for example, is used or wet etching in which an acidic etching solution is used.

The order of the protection coating removal step, the resist removal step, and the intermediate layer removal step are not particularly limited. Two steps or three steps of the protection coating removal step, the resist removal step, and the intermediate layer removal step may be simultaneously performed.

Subsequently, a second processing step of forming the multiple second openings 41 in the second layer 40 is performed. For example, as illustrated in FIG. 18, the second layer 40 is irradiated with a laser L from the third surface 401. This enables the second openings 41 to be formed in the second layer 40. Examples of the laser L can include a KrF excimer laser having a wavelength of 248 nm and a YAG laser having a wavelength of 355 nm.

The second processing step may be performed with a protection film or a protection coating formed on the fourth surface 402 of the second layer 40.

The protection film is a member that is attached to the fourth surface 402. For example, the protection film includes a resin film and an adhesive layer. The protection film is attached to the fourth surface 402 such that the adhesive layer is in contact with the fourth surface 402. The adhesive layer may be a sticky layer and an adsorption layer.

The protection coating is formed in a manner in which a liquid that contains resin is applied to the fourth surface 402. Examples of an application method include a bar coating method, a spin coating method, and a spray coating method.

The protection film or the protection coating may be removed after the second processing step ends.

The reactivity of the protection film or the protection coating to the laser is preferably lower than that of the second layer 40 to the laser. The reactivity means a rate at which the protection film, the protection coating, or the second layer 40 is processed by using the laser.

At the second processing step, the multilayer body 22 is first placed on a stage such that the fourth surface 402 faces a stage surface. Subsequently, the position of an irradiation head with respect to the multilayer body 22 is adjusted. At the step of adjusting the position, the irradiation head may be moved, or the stage may be moved. The irradiation with the laser and the adjustment of the position are repeated, and consequently, the multiple second openings 41 can be formed in the second layer 40. In this way, the mask 20 illustrated in FIG. 5A can be obtained.

Alternatively, a laser mask that corresponds to the pattern of the multiple second openings 41 may be used. In this case, a condensing lens may be installed between the laser mask and the second layer 40. The multiple second openings 41 can be formed by using a laser processing method with a reduction projection optical system.

The entire region of the second layer 40 that overlaps one of the first openings 31 may be irradiated with the laser at an irradiation step performed once. For example, the laser mask may include multiple transmissive portions that correspond to the multiple second openings 41 that overlap one of the first openings 31, and the laser may simultaneously pass through the multiple transmissive portions. In this case, the multiple second openings 41 that overlap one of the first openings 31 are formed at the irradiation step performed once with the laser. One of the first openings 31 may correspond to a single screen of an organic EL display device as described above. In this method, the precision of the positions of multiple organic layers that form a single screen can be inhibited from decreasing due to the movement of the irradiation head or the stage. The “irradiation step performed once” means a step at which the laser is radiated with the relative position of the second layer 40 with respect to the laser being constant. This method may be used in the case where the dimension of one of the first openings 31 is relatively small. For example, the length of a side of each first opening 31 is 6 mm or less. For example, the length of a side of each first opening 31 may be 2 mm or more.

The multiple second openings 41 that overlap one of the first openings 31 may be formed at the irradiation step performed twice or more with the laser. For example, the laser may cumulatively pass through a single pattern region of the laser mask at the irradiation step performed twice or more with the laser. For example, the laser may cumulatively pass through the single pattern region of the laser mask in a manner in which the laser is radiated while the irradiation head is moved with respect to the laser mask. The single pattern region of the laser mask includes the multiple transmissive portions that correspond to the multiple second openings 41 that overlap one of the first openings 31. This method may be used in the case where the dimension of one of the first openings 31 is relatively large. For example, the length of a side of each first opening 31 is 10 mm or more. For example, the length of a side of each first opening 31 may be 40 mm or less.

One of the second openings 41 may be formed by a single laser shot.

One of the second openings 41 may be formed by two or more laser shots. In this case, the depths of the recessed portions that are formed on the second layer 40 by the single laser shot are less than the thickness of the second layer 40.

The laser may be adjusted such that the second wall surfaces 42 of the second openings 41 include the tapered surfaces 42a.

For example, the irradiation area of the laser that corresponds to the second openings 41 may be changed for every shot. For example, the second processing step may include a first shot step at which the third surface 401 is irradiated with the laser having a first irradiation area and a second shot step at which the third surface 401 is irradiated with the laser having a second irradiation area larger than the first irradiation area. The first irradiation area may correspond to the areas of the second openings 41 at the fourth surface 402. The second irradiation area may correspond to the areas of the second openings 41 at the third surface 401. The second processing step may include 3 or more shot steps. The irradiation area and intensity of the laser at each shot step is set such that the second wall surfaces 42 include the tapered surfaces 42a.

For example, a single transmissive portion of the laser mask may have a first transmissive region having first transmittance and a second transmissive region having second transmittance less than the first transmittance. The contour of the first transmissive region may correspond to the contours of the second openings 41 at the fourth surface 402. The second transmissive region may surround the first transmissive region in plan view. The contour of the second transmissive region may correspond to the contours of the second openings 41 at the third surface 401. A single transmissive portion may include 3 or more transmissive regions. The shape and transmittance of each transmissive region are set such that the second wall surfaces 42 include the tapered surfaces 42a.

The second openings 41 may be formed in the second layer 40 by using a means other than the laser although this is not illustrated. For example, the second openings 41 may be formed in the second layer 40 by using a photolithography method. In this case, the second layer 40 contains a photosensitive resin material.

An example of a method of manufacturing the organic device 100 by using the mask 20 will now be described.

The substrate 110 on which the first electrodes 120 are formed is first prepared. The substrate 110 may be a silicon wafer. For example, the first electrodes 120 may be formed in a manner in which a conductive layer for forming the first electrodes 120 is formed on the substrate 110 by using, for example, the vacuum film formation method, and subsequently, the conductive layer is patterned by using the photolithography method. The conductive layer may be patterned by using the device that performs the semiconductor manufacturing step. Each insulating layer 160 that is located between two of the first electrodes 120 adjacent to each other may be formed on the substrate 110.

Subsequently, the organic layers 130 that include, for example, the first organic layers 130A and the second organic layers 130B are formed on the first electrodes 120. For example, the first organic layers 130A are first formed by using the vapor deposition method in which a first mask 20 is used. The first mask 20 includes the second openings 41 that correspond to the first organic layers 130A. Subsequently, the second organic layers 130B are formed by using the vapor deposition method in which a second mask 20 is used. The second mask 20 includes the second openings 41 that correspond to the second organic layers 130B. Subsequently, the third organic layers are formed by using the vapor deposition method in which a third mask 20 is used. The third mask 20 includes the second openings 41 that correspond to the third organic layers.

Subsequently, the second electrodes 140 are formed on the organic layers 130. For example, as illustrated in FIG. 1, the second electrodes 140 may be formed on the whole of the first surface 111 by using, for example, a vacuum film formation method. Alternatively, the second electrodes 140 may be formed by using the vapor deposition method in which the mask 20 is used as in the organic layers 130 although this is not illustrated. Subsequently, a sealing layer not illustrated, for example, may be formed on the second electrodes 140. In this way, the organic device 100 can be obtained.

The multiple organic devices 100 may be formed on the single substrate 110. One of the organic device 100 may correspond to one of the first openings 31 of the mask 20. In this case, a step of cutting the substrate 110 may be performed. For example, the substrate 110 is cut along a region of the substrate 110 that corresponds to the inner region 36 of the mask 20. This enables the multiple organic devices 100 to be obtained.

The effects of the mask 20 in the case where the organic layers 130 and the second electrodes 140, for example, are formed by using the vapor deposition method in which the mask 20 is used will be described.

The mask 20 includes the first layer 30 that contains silicon or a silicon compound. For this reason, in the case where the substrate 110 contains silicon, the thermal expansion of the substrate 110 and the thermal expansion of the mask 20 can be inhibited from differing from each other. This enables the precision of the positions and shapes of vapor deposition layers such as the organic layers 130 and the second electrodes 140, for example, to be inhibited from decreasing due to the thermal expansion of the mask 20. Accordingly, the organic device 100 that has a high element density can be provided.

The mask 20 includes the second layer 40 that includes the multiple second openings 41. The second layer 40 contains the resin material. The second layer 40 is provided separately from the first layer 30, the thickness of the second layer 40 can be consequently decreased, and accordingly, shadow can be inhibited from occurring at the vapor deposition step. The intervals S6 between the first wall surfaces 32 and the second openings 41 in plan view are appropriately ensured, and consequently, the thickness of the first layer 30 can be appropriately ensured while shadow is inhibited from occurring. This enables the first layer 30 to be inhibited from being damaged when the mask 20 is handled, for example, when the mask is moved. The second layer 40 contains the resin material, and accordingly, the second layer 40 is likely to come into contact with the substrate 110 or a component on the substrate 110. It is thought that the reason is (A) or (B) described below.
(A) The van der Waals force is applied.
(B) The resin material is flexible, and accordingly, the second layer 40 is likely to deform depending on the shape of the component of the substrate 110.

Since the second layer 40 is likely to come into contact with the substrate 110 or the component on the substrate 110, a gap can be inhibited from being formed between the second layer 40 and the substrate 110 or the component on the substrate 110. This also inhibits shadow from occurring. At the vapor deposition step, the second layer 40 is preferably in contact with the substrate 110 or the component on the substrate 110. In the case where the protection coating is formed on the fourth surface 402, at the vapor deposition step, the protection coating is preferably in contact with the substrate 110 or the component on the substrate 110. The thickness of the protection coating is preferably 1.0 μm or less, may be 0.8 μm or less, or may be 0.6 μm or less.

The second layer 40 that contains the resin material is coupled with the first layer 30 with the intermediate layer 50 interposed therebetween, and accordingly, the debris of the first layer 30 can be inhibited from scattering even through the first layer 30 is damaged.

The peripheral region 43 of the second layer 40 of the mask 20 is fixed to the second surface 302 of the first layer 30. For this reason, the effective region 44 of the second layer 40 can be inhibited from bending. This enables the positions of the second openings 41 that are formed in the effective region 44 to be inhibited from changing.

An embodiment described above can be modified in various ways. Other embodiments will now be described with reference to the drawings as needed. In the description below and the drawings that are used for the description below, as for a portion that can be the same as in an embodiment described above, the same reference sign as the reference sign that is used for a corresponding portion according to an embodiment described above is used. A duplicated description is omitted. In the case where the actions and the effects that are obtained according to an embodiment described above are obviously obtained also according to the other embodiments, the description thereof is omitted in some cases.

### Second Embodiment

A second embodiment will be described with reference to FIG. 19.

The multilayer body 22 is prepared as in the case of the first embodiment. Subsequently, the first processing step of forming the first openings 31 in the first layer 30 is performed.

Subsequently, the second processing step of forming the multiple second openings 41 in the second layer 40 is performed. For example, as illustrated in FIG. 19, the laser L is radiated from the intermediate layer 50 toward the multilayer body that includes the second layer 40 and the intermediate layer 50. This enables openings to be formed in the intermediate layer 50 and enables the second openings 41 to be formed in the second layer 40.

According to the second embodiment, the third surface 401 of the second layer 40 is covered by the intermediate layer 50 at the step of radiating the laser L. For this reason, a scattering object that is produced due to the radiation of the laser can be inhibited from being attached to the third surface 401.

Subsequently, the intermediate layer removal step of removing the intermediate layer 50 is performed. For example, the etchant for the intermediate layer 50 is supplied to the first openings 31. This enables the intermediate layer 50 that overlaps the first openings 31 in plan view to be removed.

### Third Embodiment

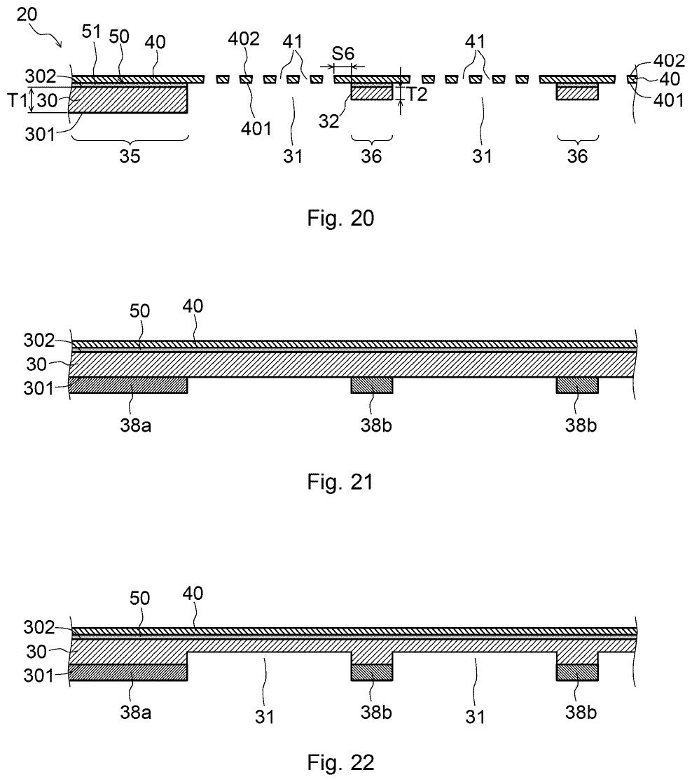

FIG. 20 is a sectional view of an example of a mask 20 according to a third embodiment. As illustrated in FIG. 20, the thickness T2 of the first layer 30 in the inner region 36 may be less than the thickness T1 of the outer region 35.

For example, the thickness T2 is 10 μm or more, may be 30 μm or more, or may be 50 μm or more. For example, the thickness T2 is 300 μm or less, may be 200 μm or less, or may be 100 μm or less.

For example, the ratio of the thickness T2 to the thickness T1 is 1% or more, may be 10% or more, or may be 20% or more. For example, the ratio of the thickness T2 of the thickness T1 is 90% or less, may be 70% or less, or may be 50% or less.

A method of manufacturing of the mask 20 will be described with reference to FIG. 21 to FIG. 24. The multilayer body 22 is first prepared as in the case of the first embodiment. Subsequently, as illustrated in FIG. 21, a first resist layer 38a and a second resist layer 38b are formed on the first surface 301 of the first layer 30. The first resist layer 38a is formed at a position that corresponds to that of the outer region 35. The second resist layer 38b is formed at a position that corresponds to that of the inner region 36.

The material of the first resist layer 38a differs from the material of the second resist layer 38b. For example, the first resist layer 38a contains a silicon oxide film, and the second resist layer 38b contains photoresist.

Subsequently, the first processing step of forming the first openings 31 in the first layer 30 is performed. As illustrated in FIG. 22, the first processing step is stopped before the first openings 31 reach the second surface 302.

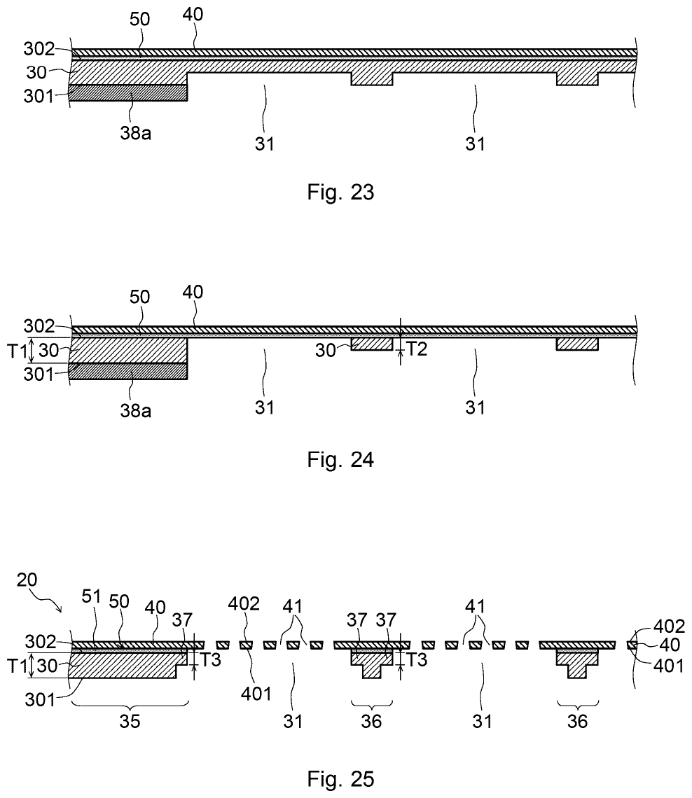

Subsequently, as illustrated in FIG. 23, the second resist layer 38b is removed. For example, a second resist processing liquid is supplied to the first surface 301. It is preferable that the second resist processing liquid be not capable of etching the first resist layer 38a. In other words, the first resist layer 38a preferably has resistance against the second resist processing liquid. This enables the first resist layer 38a to remain on the first surface 301 as illustrated in FIG. 23. For example, the second resist processing liquid contains N-methyl-2-pyrrolidone. The second resist layer 38b may be removed in a manner in which the second resist layer 38b is irradiated with oxygen plasma.

Subsequently, the first processing step of forming the first openings 31 in the first layer 30 is resumed. As illustrated in FIG. 24, the first processing step continues until the first openings 31 reach the second surface 302. At the first processing step that is resumed, the first layer 30 that corresponds to the inner region 36 is also etched. For this reason, the thickness T2 of the first layer 30 that corresponds to the inner region 36 is less than the thickness T1 of the first layer 30 that is covered by the first resist layer 38a.

Subsequently, the first resist layer 38a is removed. For example, a first resist processing liquid is supplied to the first surface 301. For example, the first resist processing liquid contains hydrofluoric acid. The first resist layer 38a may be removed by dry etching in which CF₄ gas, for example, is used.

The protection coating removal step, the intermediate layer removal step, and the second processing step, for example, are performed as in the case of the first embodiment. This enables the mask 20 illustrated in FIG. 20 to be obtained.

According to the present embodiment, the thickness T2 in the inner region 36 is decreased, and consequently, shadow can be inhibited from occurring at the second openings 41 close to the first wall surfaces 32 in the inner region 36.

### Fourth Embodiment

FIG. 25 is a sectional view of an example of a mask 20 according to a fourth embodiment. As illustrated in FIG. 25, only portions in the inner region 36 may have a thickness T3 less than the thickness T1. The portions that have the thickness T3 are also referred to as thin portions 37. The thin portions 37 are preferably adjacent to the first openings 31 in plan view. This enables shadow to be inhibited from occurring at the second openings 41 close to the thin portions 37.

As illustrated in FIG. 25, the outer region 35 may include the thin portions 37. The thin portions 37 are preferably adjacent to the first openings 31 in plan view. This enables shadow to be inhibited from occurring at the second openings 41 close to the thin portions 37.

A method of manufacturing the mask 20 will be described. The multilayer body 22 is first prepared as in the case of the first embodiment. Subsequently, the second resist layer 38b is formed on a portion of the first layer 30 that corresponds to the thin portions 37. The first resist layer 38a is formed on a portion of the first layer 30 that corresponds to the inner region 36 other than the thin portions 37. The first resist layer 38a is formed on a portion of the first layer 30 that corresponds to the outer region 35 other than the thin portions 37. Subsequently, the first processing step, the second resist removal step, the first processing step, the first resist removal step, the protection coating removal step, the intermediate layer removal step, and the second processing step, for example, are performed as in the case of the third embodiment. This enables the mask 20 illustrated in FIG. 25 to be obtained.

According to the present embodiment, the first layer 30 includes the thin portions 37, and consequently, shadow can be inhibited from occurring at the second openings 41 close to the thin portions 37. The inner region 36 includes portions that are thicker than the thin portions 37, and consequently, the strength of the inner region 36 can be increased.

### Fifth Embodiment

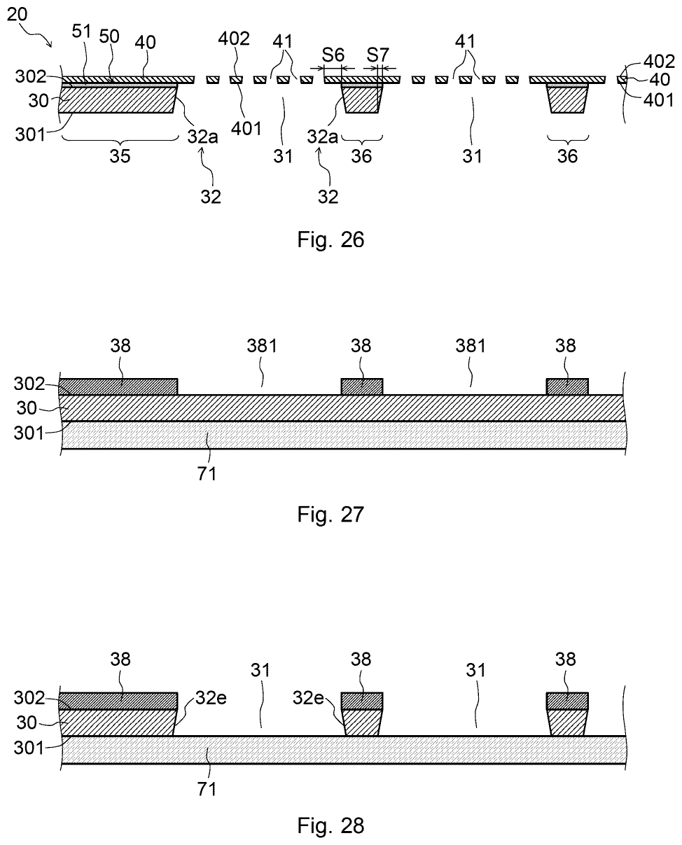

FIG. 26 is a sectional view of an example of a mask 20 according to a fifth embodiment. As illustrated in FIG. 26, the first wall surfaces 32 may include tapered surfaces 32a that extend outward as the positions are nearer to the first surface 301.

The word “outward” is the direction away from the center of each first opening 31 in the in-plane direction of the first surface 301 as described above. The second openings 41 overlap the first openings 31 in plan view. Accordingly, the tapered surfaces 32a extend so as to be separated from the second openings 41 in the in-plane direction of the first surface 301 as the positions are nearer to the first surface 301. The first wall surfaces 32 include the tapered surfaces 32a, and consequently, shadow can be inhibited from occurring at the second openings 41 close to the tapered surfaces 32a.

In FIG. 26, a reference sign of S7 represents the width of each tapered surface 32a in the direction in which the first openings 31 are arranged. For example, the width S7 is 2 μm or more, may be 5 μm or more, or may be 10 μm or more. For example, the width S7 is 100 μm or less, may be 50 μm or less, or may be 20 μm or less.

A method of manufacturing the mask 20 will be described with reference to FIG. 27 to FIG. 30. The first layer 30 is first prepared as in the case of the first embodiment. As illustrated in FIG. 27, a support substrate 71 may be mounted on the first surface 301 of the first layer 30. Subsequently, as illustrated in FIG. 27, the resist formation step of partly forming the resist layer 38 on the second surface 302 of the first layer 30 is performed. The resist openings 381 that face the first openings 31 are formed in the resist layer 38. The resist layer 38 may be photoresist or may be a silicon oxide film.

Subsequently, as illustrated in FIG. 28, the first processing step of forming the first openings 31 in the first layer 30 by etching the first layer 30 from the second surface 302 is performed. At the first processing step, the dry etching step and the protection coating formation step are alternately repeated until holes reach the first surface 301.

The etching conditions are adjusted such that the dimensions of the holes in the in-plane direction of the first surface 301 increase as the positions are nearer to the first surface 301 at the first processing step. For example, the intensity or time of etching is increased as the positions are nearer to the first surface 301. As illustrated in FIG. 28, this enables the first wall surfaces 32 of the first openings 31 to include the tapered surfaces 32a.

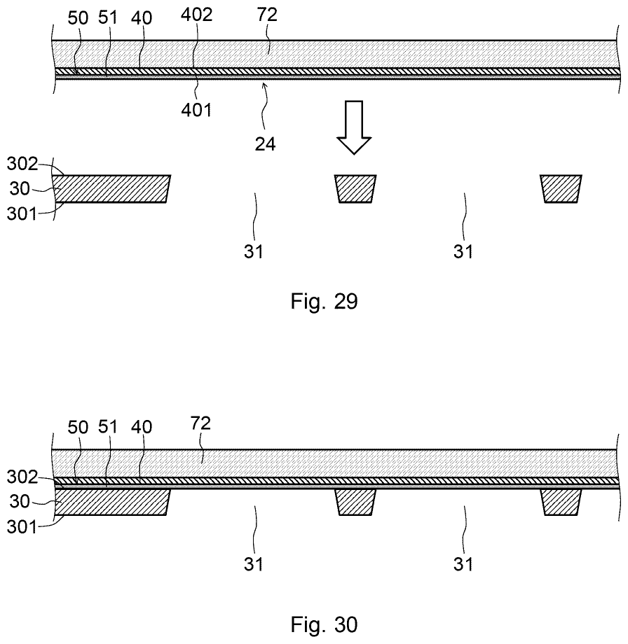

Subsequently, the support substrate 71 is removed from the first layer 30. As illustrated in FIG. 29, a multilayer body 24 that includes the second layer 40 and the intermediate layer 50 is prepared. The second layer 40 includes the third surface 401 that faces the second surface 302 of the first layer 30 and the fourth surface 402 that is located opposite the third surface 401. The intermediate layer 50 is located between the second surface 302 and the third surface 401. The intermediate layer 50 may include the first intermediate layer 51 that functions as a joining layer. As illustrated in FIG. 29, a support substrate 72 may be mounted on the fourth surface 402 of the second layer 40.

Subsequently, a joining step of joining the second layer 40 to the second surface 302 of the first layer 30 is performed. As illustrated in FIG. 30, the intermediate layer 50 of the multilayer body 24 is joined to the first layer 30, and consequently, the second layer 40 is joined to the first layer 30 with the intermediate layer 50 interposed therebetween. Subsequently, the support substrate 72 is removed from the second layer 40. The intermediate layer removal step and the second processing step, for example, are performed as in the case of the first embodiment. This enables the mask 20 illustrated in FIG. 26 to be obtained.

In an example illustrated in FIG. 27 to FIG. 30, the multilayer body 24 that includes the second layer 40 and the intermediate layer 50 is joined to the first layer 30. However, a method of providing the intermediate layer 50 is not limited provided that the intermediate layer 50 is located between the second surface 302 and the third surface 401 in the state of the mask 20. For example, at the first processing step illustrated in FIG. 28, the intermediate layer 50 may be disposed on the second surface 302 of the first layer 30. At the joining step of joining the second layer 40 to the first layer 30, the intermediate layer 50 may be disposed such that the intermediate layer 50 is interposed between the second layer 40 and the first layer 30.

According to the present embodiment, the first wall surfaces 32 include the tapered surfaces 32a, and consequently, shadow can be inhibited from occurring at the second openings 41 close to the tapered surfaces 32a.

### Sixth Embodiment

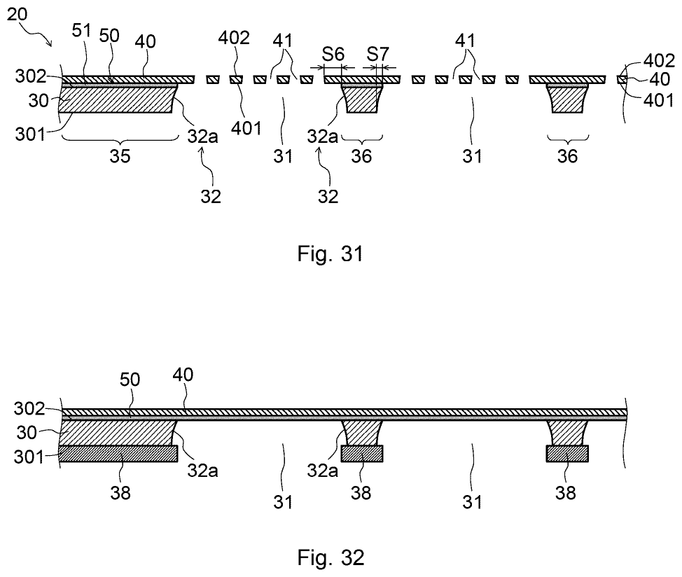

FIG. 31 is a sectional view of an example of a mask 20 according to a sixth embodiment. As illustrated in FIG. 31, the tapered surfaces 32a of the first wall surfaces 32 of the first layer 30 may include outwardly convex curved surfaces. Also, in this case, shadow can be inhibited from occurring at the second openings 41 close to the tapered surfaces 32a.

A method of manufacturing the mask 20 will be described. The multilayer body 22 is prepared as in the case of the first embodiment. Subsequently, the resist formation step of partly forming the resist layer 38 on the first surface 301 of the first layer 30 is performed.

Subsequently, the first processing step of forming the first openings 31 in the first layer 30 is performed. For example, the first layer 30 is processed from the first surface 301 up to the second surface 302 by wet etching. The first layer 30 may be processed from the first surface 301 up to the second surface 302 by dry etching. As illustrated in FIG. 32, this enables the tapered surfaces 32a that curve to be formed.

Subsequently, the resist removal step, the intermediate layer removal step, and the second processing step, for example, are performed as in the case of the first embodiment. This enables the mask 20 illustrated in FIG. 31 to be obtained.

### Seventh Embodiment

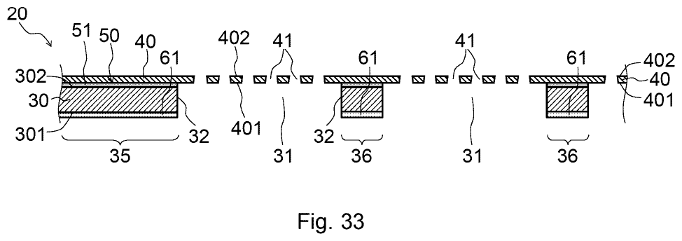

FIG. 33 is a sectional view of an example of a mask 20 according to a seventh embodiment. As illustrated in FIG. 33, the mask 20 may include a stress adjustment layer 61 that is located on the first surface 301 of the first layer 30. The stress adjustment layer 61 acts on the first surface 301 of the first layer 30 so as to cancel out stress that is applied by the second layer 40 to the second surface 302 of the first layer 30. For example, in the case where the second layer 40 applies tensile stress to the second surface 302, the stress adjustment layer 61 similarly applies tensile stress to the first surface 301. In contrast, in the case where the second layer 40 applies compressive stress to the second surface 302, the stress adjustment layer 61 similarly applies compressive stress to the first surface 301.

The material of the stress adjustment layer 61 may be an organic material or an inorganic material. The material of the stress adjustment layer 61 may be selected depending on the stress to be applied by the stress adjustment layer 61 to the first surface 301. For example, the stress adjustment layer 61 that contains a silicon oxide is capable of applying compressive stress to the first surface 301. The stress adjustment layer 61 that contains a silicon nitride is capable of applying tensile stress to the first surface 301.

The mask 20 may include a close-contact layer that is located between the first surface 301 and the stress adjustment layer 61 although this is not illustrated. The adhesion of the close-contact layer to the first surface 301 is greater than the adhesion of the stress adjustment layer 61 to the first surface 301. The close-contact layer may include a single layer or may include two or more layers.

In the case where the mask 20 includes the close-contact layer, the sum of the stress of the close-contact layer and the stress of the stress adjustment layer 61 is applied to the first surface 301. The material and thickness of the stress adjustment layer 61, for example, are adjusted in consideration of the stress of the close-contact layer.

According to the present embodiment, the stress adjustment layer 61 is formed on the first surface 301, and consequently, stress that is applied to the first layer 30 can be decreased. This enables the first layer 30 to be inhibited from deforming, for example, warping.

### Eighth Embodiment

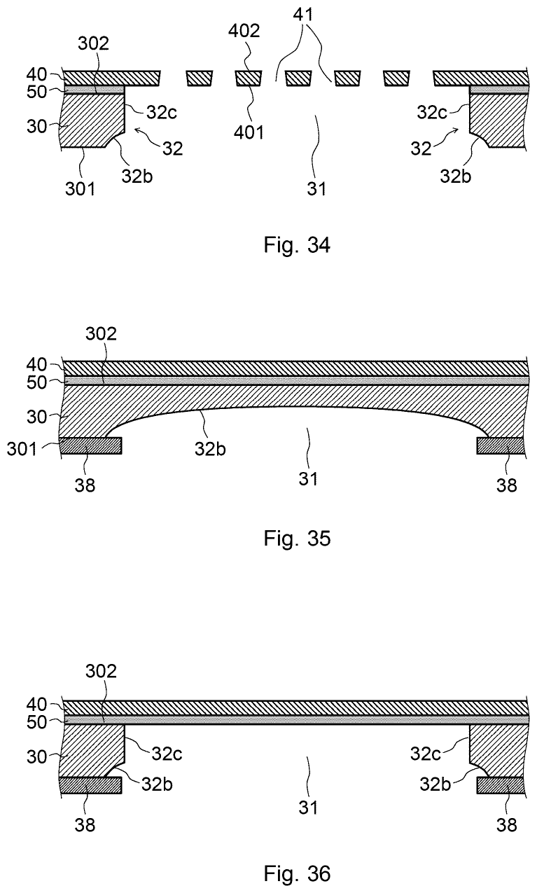

FIG. 34 is a sectional view of an example of a mask 20 according to an eighth embodiment. As illustrated in FIG. 34, the first wall surfaces 32 of the first layer 30 may include curved surfaces 32b that are connected to the first surface 301. The curved surfaces 32b may not extend to the second surface 302. For example, the first wall surfaces 32 may include the curved surfaces 32b that are connected to the first surface 301 and uneven surfaces 32c that are connected to the second surface 302. The uneven surfaces 32c include the multiple recessed portions 33 that are arranged in the thickness direction of the first layer 30.

A method of manufacturing the mask 20 will be described. The multilayer body 22 is prepared as in the case of the first embodiment. Subsequently, the resist formation step of partly forming the resist layer 38 on the first surface 301 of the first layer 30 is performed.

Subsequently, the first layer 30 is processed from the first surface 301 by wet etching as in the case of the sixth embodiment. As illustrated in FIG. 35, this enables the curved surfaces 32b that are connected to the first surface 301 to be formed. The curved surfaces 32b have an outwardly convex shape. The wet etching ends before the curved surfaces 32b reach the second surface 302. The first layer 30 may be processed from the first surface 301 by isotropic dry etching.

Subsequently, the dry etching step and the protection coating formation step are repeated until the first openings 31 reach the intermediate layer 50 as in the case of the first embodiment. As illustrated in FIG. 36, this enables the uneven surfaces 32c that are connected to the curved surfaces 32b and the second surface 302 to be formed.

The curved surfaces 32b are also the tapered surfaces 32a that extend outward as the positions are nearer to the first surface 301. For this reason, shadow can be inhibited from occurring at the second openings 41 close to the curved surfaces 32b.

### Ninth Embodiment

In examples described according to the embodiments described above, one of the first openings 31 overlaps the single effective region 44 in plan view. In an example described according to the present embodiment, a single first opening 31 overlaps two or more effective regions 44.

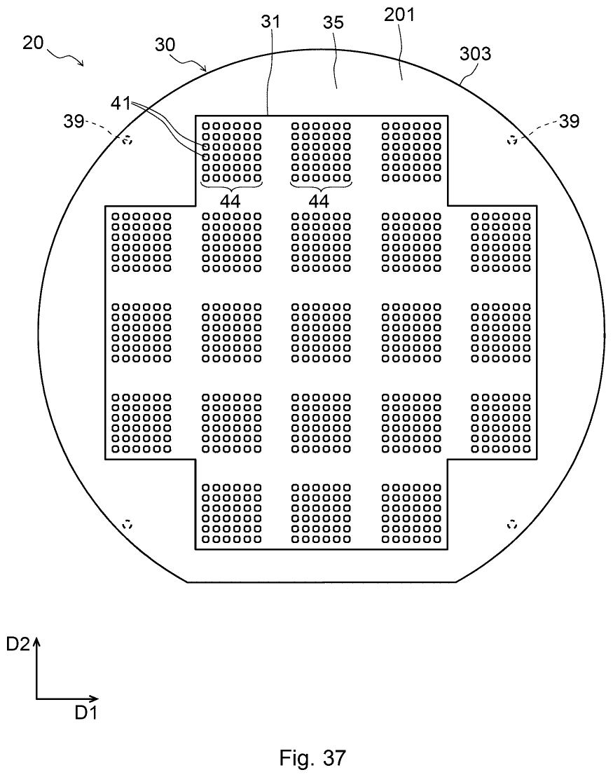

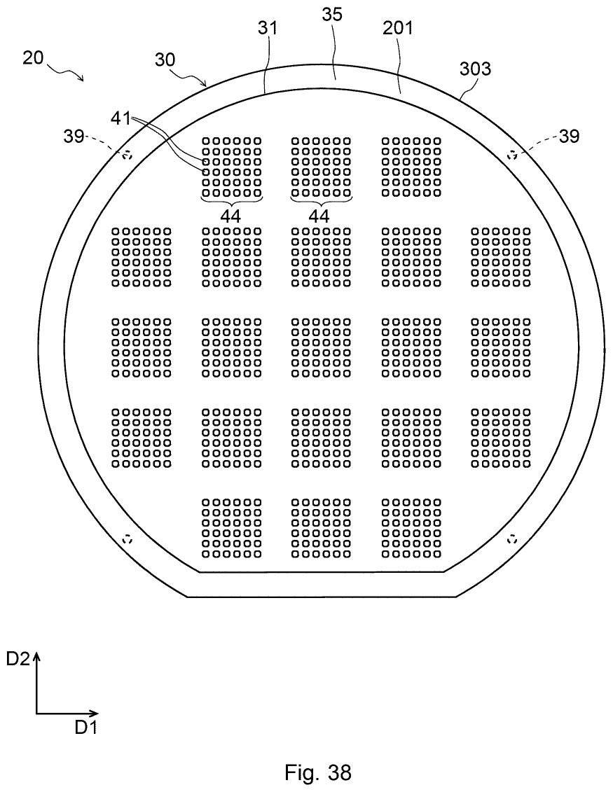

For example, as illustrated in FIG. 37 or FIG. 38, the first layer 30 may include the single first opening 31, and the single first opening 31 may overlap two or more effective regions 44. As illustrated in FIG. 37, the first opening 31 may have a contour that includes multiple straight sides in plan view. As illustrated in FIG. 38, the first opening 31 may have a contour that includes a curved portion in plan view. As illustrated in FIG. 38, the contour of the first opening 31 may be similar to the contour of the first layer 30.

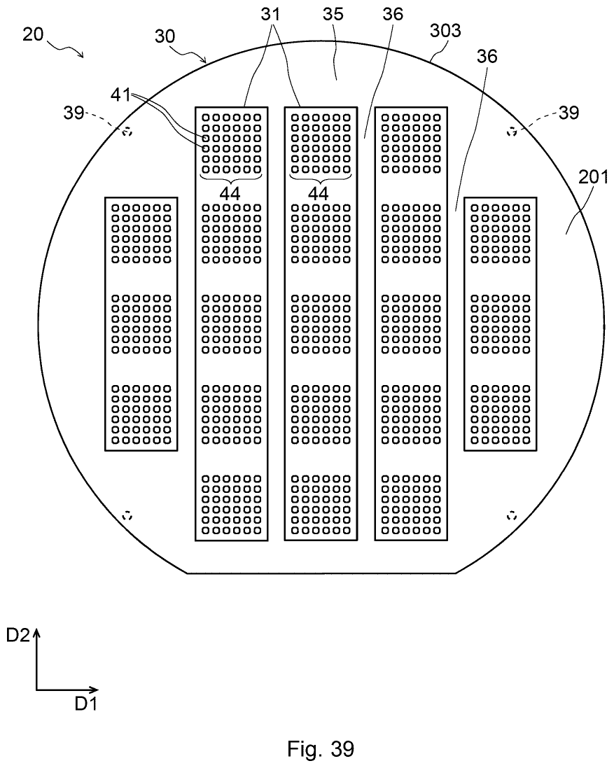

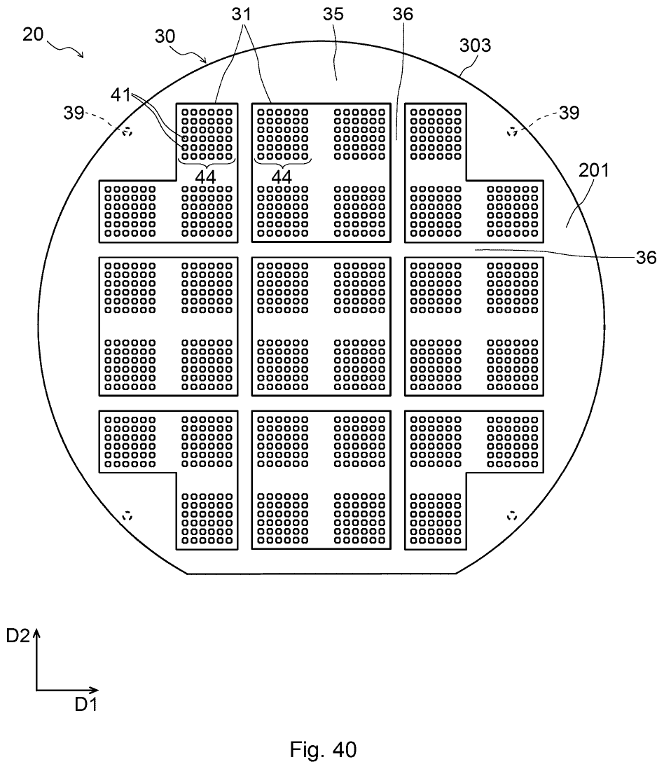

For example, as illustrated in FIG. 39 or FIG. 40, the first layer 30 may include two or more first openings 31, and each of the first openings 31 may overlap two or more effective regions 44. As illustrated in FIG. 39, each of the first openings 31 may surround columns of two or more effective regions 44 that are arranged in the second direction D2 in plan view. As illustrated in FIG. 40, each of the first openings 31 may surround two or more effective regions 44 that are arranged in the first direction D1 and two or more effective regions 44 that are arranged in the second direction D2 in plan view.

According to the present embodiment, the area of the first layer 30 can be smaller than those according to the embodiments described above in plan view. Consequently, there is a possibility that the adhesion of the exit surface 202 of the mask 20 to the substrate 110 can be increased.

### Tenth Embodiment

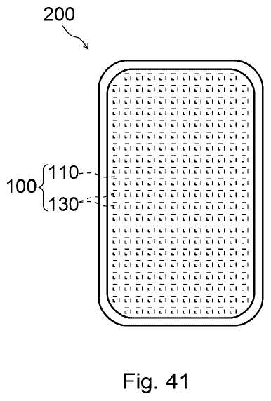

FIG. 41 illustrates an example of a device 200 that includes the organic device 100. The device 200 includes the substrate 110 and the organic layers 130. The organic layers 130 are formed by using the vapor deposition method in which the mask 20 is used. An example of the device 200 is a smart phone. The device 200 may be a tablet terminal or a wearable terminal. Examples of the wearable terminal include smart glasses and a head-mounted display.

### Eleventh Embodiment

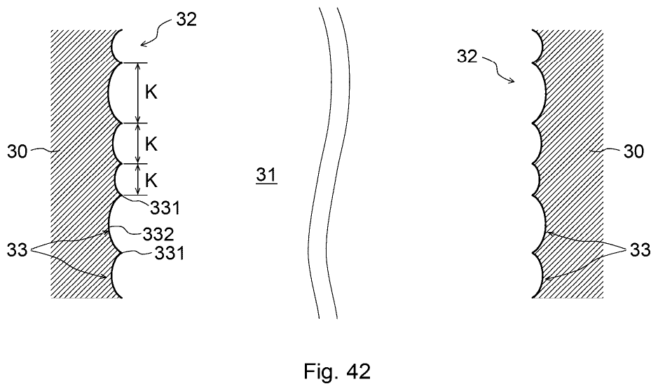

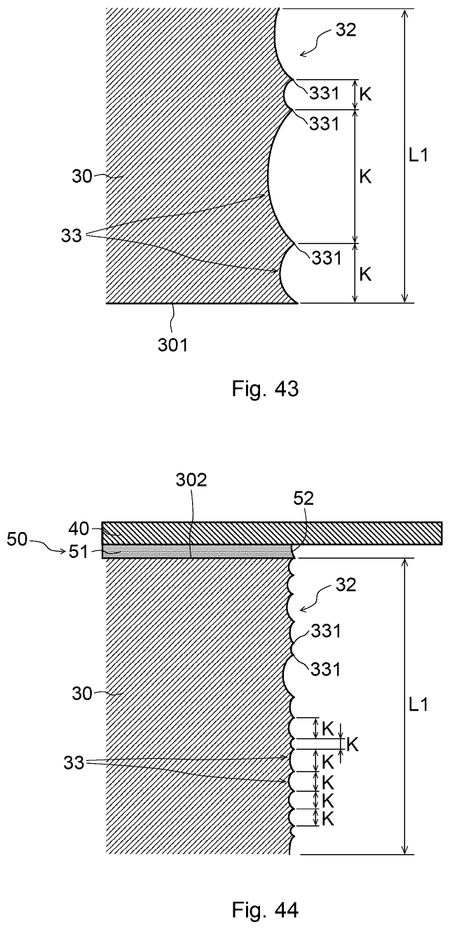

FIG. 42 is a sectional view of an example of the first wall surfaces 32 of the first openings 31 of the mask 20 according to an eleventh embodiment. A reference sign of K represents an interval between top portions 331 of two recessed portions 33 adjacent to each other in the thickness direction of the first layer 30. As illustrated in FIG. 42, the interval K may not be constant. In this case, the period P of the recessed portions 33 is calculated by averaging the values of the interval K for the multiple recessed portions 33 that are located in a certain range.

FIG. 43 is a sectional view of an example of the first wall surfaces 32 of the first openings 31 near the first surface 301 of the first layer 30. The first period P1 described above is calculated by averaging the values of the interval K of the multiple recessed portions 33 that are located in the range of a distance L1 from the first surface 301 in the thickness direction.

FIG. 44 is a sectional view of an example of the first wall surfaces 32 of the first openings 31 near the second surface 302 of the first layer 30. The second period P2 described above is calculated by averaging the values of the interval K of the multiple recessed portions 33 that are located in the range of the distance L1 from the second surface 302 in the thickness direction.

The second period P2 may be shorter than the first period P1 as in the case of the first embodiment. For example, P2/P1 is 0.98 or less, may be 0.95 or less, or may be 0.90 or less. For example, P2/P1 is 0.10 or more, may be 0.20 or more, or may be 0.30 or more.

The distance L1 is determined depending on the thickness T1 of the first layer 30. For example, the distance L1 is equal to 4% of the thickness T1. For example, in the case where the thickness T1 of the first layer 30 is 625 μm, the distance L1 is 25 μm.

The interval K can be measured by observing an image of a section of the first layer 30 by using the scanning electron microscope. A sample for observation can be obtained in a manner in which the first layer 30 is cut by the focused ion beam device. The first layer 30 is cut along lines that pass through the centers of the first openings 31 in plan view. The centers of the first openings 31 are visually determined by an operator who operates the focused ion beam device. In some cases, the lines along which the first layer 30 is cut are shifted from the centers of the first openings 31 due to the precision of processing. A shift of 3 mm or less from the centers of the first openings 31 is permitted.

Examples of the result of measurement of the interval K near the first surface 301 and the result of measurement of the interval K near the second surface 302 are illustrated in Table later. The interval K near the first surface 301 and near the second surface 302 was measured regarding six first openings 31. The average value of the interval K near the first surface 301 corresponds to the first period P1 described above. The average value of the interval K near the second surface 302 corresponds to the second period P2 described above. The thickness of the first layer 30 was 625 μm. The dimension S2 of each first opening 31 was 16 mm.

TABLE 1

| | Near first surface | Near second surface |
|---|---|---|
| Minimum value of interval K | 2.06 μm | 0.68 μm |
| Maximum value of interval K | 9.34 μm | 4.10 μm |
| Average value | 5.98 μm | 1.96 μm |

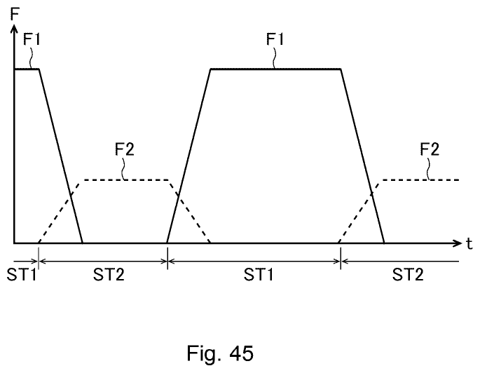

FIG. 45 illustrates a diagram for describing an example of why the interval K of the recessed portions 33 of the first openings 31 is non-uniform. The first openings 31 are formed by performing the first processing step described above. At the first processing step, the dry etching step of dry etching the first layer 30 from the first surface 301 and the protection coating formation step of forming the protection coatings on the wall surfaces and the bottom surfaces of the holes that are formed by dry etching are repeated in the chamber. A vertical axis in FIG. 45 represents the flow rate of gas that is supplied into the chamber. A horizontal axis represents time. A reference sign of F1 represents the flow rate of etching gas that is supplied into the chamber at the dry etching step ST1. An example of the etching gas is SF₆ gas. A reference sign of F2 represents the flow rate of material gas that is supplied into the chamber at the protection coating formation step ST2. An example of the material gas is C₄F₈ gas.

At the first processing step, the etching gas and the material gas are mixed in the chamber in some cases. For example, as illustrated in FIG. 45, the etching gas remains in the chamber right after the step is changed from the dry etching step ST1 into the protection coating formation step ST2 in some cases. For example, as illustrated in FIG. 45, the material gas remains in the chamber right after the step is changed from the protection coating formation step ST2 into the dry etching step ST1 in some cases. The etching rate of the first layer 30 is affected by the ratio of the mixture of the etching gas and the material gas. For this reason, in the case where the ratio of the mixture of the etching gas and the material gas varies depending on position, the shapes of the recessed portions 33 can vary depending on position. For example, the interval and/or depths of the recessed portions 33 are non-uniform in some cases.

As the thickness T1 of the first layer 30 increases, the depths of the first openings 31 increase. For this reason, gas that remains in the first openings 31 is unlikely to be discharged. As a result, the etching gas and the material gas are likely to be mixed, and the shapes of the recessed portions 33 are likely to vary.

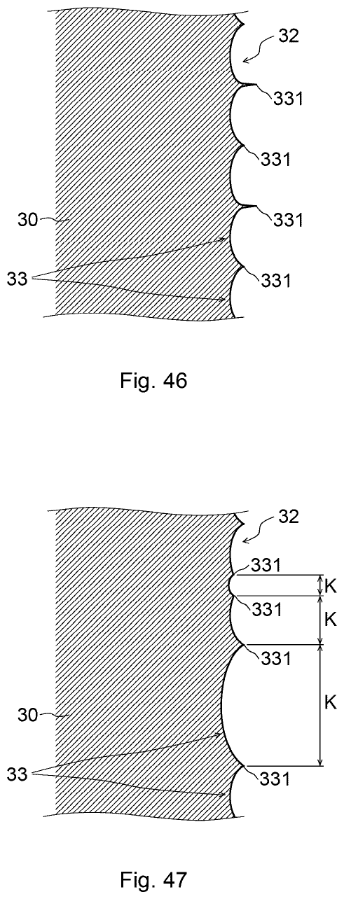

FIG. 46 and FIG. 47 are diagrams for describing an example of why the interval K of the recessed portions 33 of the first openings 31 is non-uniform. FIG. 46 illustrates an example of the recessed portions 33 that are formed by performing the first processing step. As illustrated in FIG. 46, some of the multiple top portions 331 sharply project inward. Such a sharp projecting portion is also referred to as a burr. The first processing step may include a smoothing step of removing the burr. For example, the smoothing step includes an isotropic etching process. For example, the isotropic etching process may remove the burr by using SF₆ gas.

The smoothing step may be performed not only in the case where the first wall surfaces 32 include the burr but also in the case where the first wall surfaces 32 are roughened. In an example, the roughened first wall surfaces 32 includes linear undulations. In some cases, the linear undulations appear in line with the thickness direction of the first layer 30. In the case where the first wall surfaces 32 are roughened, it can be thought that some of the first wall surfaces 32 are damaged during a step of manufacturing the mask 20, or a step of cleaning the mask 20. The smoothing step can reduce the degree of roughness of the first wall surfaces 32. For this reason, it can be inhibited that some of the first wall surfaces 32 are damaged.

FIG. 47 illustrates an example of the recessed portions 33 on which the smoothing step is performed. Some of the top portions 331 that are sharp are removed, and consequently, the interval K between the top portions 331 of the recessed portions 33 is non-uniform.

Some advantages when the interval K between the top portions 331 of the recessed portions 33 is non-uniform will be described. At least one of the multiple advantages described below is preferably gained.

A first advantage is that the regularity of the vapor deposition material 7 that is attached to the first wall surfaces 32 of the first openings 31 can be disturbed. For example, the thickness of the vapor deposition material 7 that is attached to the first wall surfaces 32 can be irregular depending on position. This enables the vapor deposition material 7 to be inhibited from being separated from the first wall surfaces 32 during the vapor deposition step unlike the case where the vapor deposition material 7 is regularly attached to the first wall surfaces 32.

A second advantage is that a cleaning solution is likely to enter a gap in the vapor deposition material 7 that is attached to the first wall surfaces 32 at the step of cleaning the mask 20. This enables a time required for the cleaning step to be decreased. The cleaning step is performed after the vapor deposition step. The mask 20 that is cleaned is used again at the vapor deposition step.

A third advantage is that a direction in which the vapor deposition material 7 moves is irregular in the case where the vapor deposition material 7 that is attached to the first wall surfaces 32 of the first openings 31 once is evaporated and moves toward the substrate 110. This enables the uniformness of the thickness of the vapor deposition layer that is formed on the first surface 111 of the substrate 110 to be improved. The vapor deposition material 7 on the first wall surfaces 32 can be evaporated in the case where the first layer 30 is heated.

Multiple components that are disclosed according to the embodiments and the modifications described above can be appropriately combined as needed. Some of components may be removed from all of the components that are disclosed according to the embodiments and the modifications described above.

1. A mask comprising:
a first layer that includes a first surface, a second surface that is located opposite the first surface, at least one first opening that extends from the first surface to the second surface, and a first wall surface that faces the first opening;
a second layer that includes a third surface that faces the second surface, a fourth surface that is located opposite the third surface, and multiple second openings that extend from the third surface to the fourth surface and that overlap the first opening in plan view; and
a first intermediate layer that is located between at least the second surface and the third surface,
wherein the first layer contains silicon,
wherein the second layer contains a resin material, and
wherein the first wall surface includes multiple recessed portions that are arranged in a thickness direction of the first layer.

2. The mask according to claim 1, wherein some of the multiple recessed portions close to the first surface are arranged in the thickness direction in a first period, and
wherein some of the multiple recessed portions close to the second surface are arranged in the thickness direction in a second period shorter than the first period.

3. The mask according to claim 1, wherein some of the multiple recessed portions close to the first surface have a first depth, and
wherein some of the multiple recessed portions close to the second surface have a second depth less than the first depth.

4. The mask according to claim 1, wherein the first intermediate layer includes a first intermediate wall surface that is located outside a contour of the first opening on the second surface.

5. The mask according to claim 1, wherein the first intermediate layer includes a first intermediate layer that has a thickness of 1 μm or less.

6. The mask according to claim 1, further comprising: a second intermediate layer that is located on the third surface of the second layer and that has a thickness of 1 μm or more.

7. The mask according to claim 1, wherein the first layer includes a plurality of the first openings, an inner region that is located between the first openings adjacent to each other in plan view, and an outer region that is located between an outer edge of the first layer and the first openings in plan view.

8. The mask according to claim 7, wherein a thickness of the inner region is less than a thickness of the outer region.

9. The mask according to claim 1, wherein a thickness of the second layer is less than a thickness of the first layer, and
wherein a thickness of the first intermediate layer is less than a thickness of the second layer.

10. The mask according to claim 1, wherein the first wall surface includes a tapered surface that extends outward as a position is nearer to the first surface.

11. The mask according to claim 1, further comprising: a stress adjustment layer that is located on the first surface.

12. The mask according to claim 1, wherein the second layer contains polyimide.

13. A method of manufacturing a mask, comprising:
a step of preparing a multilayer body including a first layer that includes a first surface and a second surface that is located opposite the first surface, a second layer that includes a third surface that faces the second surface and a fourth surface that is located opposite the third surface, and a first intermediate layer that is located between the second surface and the third surface;
a step of partly forming a resist layer on the first surface;
a first processing step of forming a first opening in the first layer by etching the first layer from the first surface; and
a second processing step of forming multiple second openings in the second layer.

14. A method of manufacturing a mask, comprising:
a step of preparing a first layer that includes a first surface and a second surface that is located opposite the first surface;
a step of partly forming a resist layer on the second surface;
a first processing step of forming a first opening in the first layer by etching the first layer from the second surface; and
a step of joining a second layer that includes a third surface that faces the second surface and a fourth surface that is located opposite the third surface to the first layer; and
a second processing step of forming multiple second openings in the second layer,
wherein the mask includes a first intermediate layer that is located between the second surface and the third surface.

15. The method according to claim 13, wherein the first processing step includes a dry etching step and a protection coating formation step that are alternately repeated.

16. The method according to claim 13, further comprising: a step of removing the resist layer before the second processing step after the first processing step.

17. The method according to claim 13, further comprising: a step of removing the first intermediate layer that overlaps the first opening in plan view before the second processing step after the first processing step.

18. The method according to claim 13, further comprising: a step of removing the first intermediate layer that overlaps the first opening in plan view after the second processing step.

19. A method of manufacturing an organic device, comprising:
a step of forming an organic layer on a substrate by using a vapor deposition method in which the mask according to claim 1 is used.
